(19) United States
(12) Patent Application Publication
(10) Pub. No.: US 2021/0035821 A1
(43) Pub. Date: Feb. 4, 2021

(54) METHODS AND APPARATUS FOR CLEANING SUBSTRATES

(71) Applicant: ACM Research (Shanghai) Inc., Shanghai (CN)

(72) Inventors: Hui Wang, Shanghai (CN); Xi Wang, Shanghai (CN); Xiaoyan Zhang, Shanghai (CN); Fufa Chen, Shanghai (CN); Fuping Chen, Shanghai (CN)

(73) Assignee: ACM Research (Shanghai) Inc., Shanghai (CN)

(21) Appl. No.: 16/964,491

(22) PCT Filed: Jan. 23, 2018
(86) PCT No.: PCT/CN2018/073810

§ 371 Date: Jul. 23, 2020

(51) Int. Cl. H01L 21/67; B08B 7/04; B08B 3/08; B08B 3/12

(52) U.S. Cl. CPC H01L 21/67051; H01L 21/67057; B08B 2203/005; B08B 3/08; B08B 3/12; B08B 7/04

(57) ABSTRACT

A method and an apparatus for cleaning a substrate are provided. The substrate (1010) comprises features (4034) of patterned structures. The method comprises placing the substrate on a substrate holder (1014) configured to rotate the substrate; applying cleaning liquid (1032) on the substrate; rotating the substrate by the substrate holder at a first rate when acoustic energy is being applied to the cleaning liquid by a transducer (1004); and rotating the substrate by the substrate holder at a second rate higher than the first rate when acoustic energy is not being applied to the cleaning liquid by the transducer.

### FIELD OF THE INVENTION

The present invention generally relates to method and apparatus for cleaning substrate. More particularly, relates to controlling the bubble cavitation generated by ultra or mega sonic device during the cleaning process to achieve a stable or controlled cavitation on the entire substrate, which removes fine particles efficiently in vias, trenches or recessed areas with high aspect ratio.

### BACKGROUND

Semiconductor devices are manufactured or fabricated on semiconductor substrates using a number of different processing steps to create transistor and interconnection elements. Recently, the transistors are built from two dimensions to three dimensions such as finFET transistors and 3D NAND memory. To electrically connect transistor terminals associated with the semiconductor substrate, conductive (e.g., metal) trenches, vias, and the like are formed in dielectric materials as part of the semiconductor device. The trenches and vias couple electrical signals and power between transistors, internal circuit of the semiconductor devices, and circuits external to the semiconductor device.

In forming the finFET transistors and interconnection elements on the semiconductor substrate may undergo, for example, masking, etching, and deposition processes to form the desired electronic circuitry of the semiconductor devices. In particular, multiple masking and plasma etching step can be performed to form a pattern of finFET, 3D NAND flash cell and or recessed areas in a dielectric layer on a semiconductor substrate that serve as fin for the transistor and or trenches and vias for the interconnection elements. In order to removal particles and contaminations in fin structure and or trench and via post etching or photo resist ashing, a wet cleaning step is necessary. Especially, when device manufacture node migrating to 14 or 16 nm and beyond, the side wall loss in fin and or trench and via is crucial for maintaining the critical dimension. In order to reduce or eliminate the side wall loss, it is important to use moderate, dilute chemicals, or sometime de-ionized water only. However, the dilute chemical or de-ionized water usually is not efficient to remove the particles in the fin structure, 3D NAND hole and or trench and via. Therefore the mechanical force such as ultra or mega sonic is needed in order to remove those particles efficiently. Ultra sonic or mega sonic wave will generate bubble cavitation which applies mechanical force to substrate structure, the violent cavitation such as transit cavitation or micro jet will damage those patterned structures. To maintain a stable or controlled cavitation is key parameters to control the mechanical force within the damage limit and at the same time efficiently to remove the particles. In the 3D NAND hole structure, the transit cavitation may not damage the hole structure, but however, the bubble cavitation saturated inside hole will stop or reduce the cleaning effects.

Mega sonic energy coupled with nozzle to clean semiconductor wafer is disclosed in U.S. Pat. No. 4,326,553. The fluid is pressurized and mega sonic energy is applied to the fluid by a mega sonic transducer. The nozzle is shaped to provide a ribbon-like jet of cleaning fluid vibrating at ultra/mega sonic frequencies for the impingement on the surface.

A source of energy vibrates an elongated probe which transmits the acoustic energy into the fluid is disclosed in U.S. Pat. No. 6,039,059. In one arrangement, fluid is sprayed onto both sides of a wafer while a probe is positioned close to an upper side. In another arrangement, a short probe is positioned with its end surface close to the surface, and the probe is moved over the surface as wafer rotates.

A source of energy vibrates a rod which rotates around it axis parallel to wafer surface is disclosed in U.S. Pat. No. 6,843,257 B2. The rod surface is etched to curve groves, such as spiral groove.

It is needed to have a better method for controlling the bubble cavitation generated by ultra or mega sonic device during the cleaning process to achieve a stable or controlled cavitation on the entire substrate, which removes fine particles efficiently in vias, trenches or recessed areas with high aspect ratio.

### SUMMARY

According to one aspect of the present invention is to disclose a method for cleaning a substrate, the substrate comprising features of patterned structures, the method comprising: placing the substrate on a substrate holder configured to rotate the substrate; applying cleaning liquid on the substrate; rotating the substrate by the substrate holder at a first rate when acoustic energy is being applied to the cleaning liquid by a transducer; and rotating the substrate by the substrate holder at a second rate higher than the first rate when acoustic energy is not being applied to the cleaning liquid by the transducer.

According to another aspect of the present invention is to disclose a method for cleaning a substrate comprising features of patterned structures, the method comprising: performing pretreatment on the substrate to remove defects that attract bubbles; applying a cleaning liquid on the substrate; controlling, based on a timer, a power supply of a transducer to deliver acoustic energy to the cleaning liquid at a first frequency and a first power level for a predetermined first time period; and controlling, based on the timer, the power supply of the transducer to deliver acoustic energy to the cleaning liquid at a second frequency and a second power level for a predetermined second time period, wherein the first and second time periods are alternately applied one after another for a predetermined number of cycles.

According to another aspect of the present invention is to disclose a method for cleaning a substrate comprising features of patterned structures, the method comprising: performing pretreatment on a cleaning liquid to remove at least a part of bubbles within the cleaning liquid; applying the cleaning liquid on the substrate; controlling, based on a timer, a power supply of a transducer to deliver acoustic energy to the cleaning liquid at a first frequency and a first power level for a predetermined first time period; and controlling, based on the timer, the power supply of the transducer to deliver acoustic energy to the cleaning liquid at a second frequency and a second power level for a predetermined second time period, wherein the first and second time periods are alternately applied one after another for a predetermined number of cycles.

According to another aspect of the present invention is to disclose an apparatus for cleaning a substrate comprising features of patterned structures, the apparatus comprising: a substrate holder configured to hold the substrate and configured to rotate the substrate; an inlet configured to apply cleaning liquid on the substrate; a transducer configured to deliver acoustic energy to the liquid; and one or more controllers configured to: control the substrate holder to rotate the substrate at a first rate while controlling the transducer to deliver acoustic energy to the cleaning liquid, and control the substrate holder to rotate the substrate at a second rate higher than the first rate while controlling the transducer not to deliver acoustic energy to the cleaning liquid.

According to another aspect of the present invention is to disclose a controller for an apparatus for cleaning a substrate, the controller being configured to: control a substrate holder to rotate the substrate at a first rate while controlling a transducer to deliver acoustic energy to cleaning liquid applied on the substrate; and control the substrate holder to rotate the substrate at a second rate higher than the first rate while controlling the transducer not to deliver acoustic energy to the cleaning liquid.

### BRIEF DESCRIPTION OF THE DRAWINGS

FIGS. 1A-1B depict an exemplary wafer cleaning apparatus using ultra/mega sonic device;

FIGS. 2A-2G depict variety of shape of ultra/mega sonic transducers;

FIG. 3 depicts bubble cavitation during wafer cleaning process;

FIGS. 4A-4B depict a transit cavitation damaging patterned structure on a wafer during cleaning process;

FIGS. 5A-5C depict thermal energy variation inside bubble during cleaning process;

FIGS. 6A-6C depict an exemplary wafer cleaning method;

FIGS. 7A-7C depict another exemplary wafer cleaning method;

FIGS. 8A-8D depict another exemplary wafer cleaning method;

FIGS. 9A-9D depict another exemplary wafer cleaning method;

FIGS. 10A-10B depict another exemplary wafer cleaning method;

FIGS. 11A-11B depict another exemplary wafer cleaning method;

FIGS. 12A-12B depict another exemplary wafer cleaning method;

FIGS. 13A-13B depict another exemplary wafer cleaning method;

FIGS. 14A-14B depict another exemplary wafer cleaning method;

FIGS. 15A-15C depict a stable cavitation damaging patterned structure on a wafer during cleaning process;

FIG. 16 depicts another exemplary wafer cleaning apparatus using ultra/mega sonic device;

FIG. 17 depicts an exemplary wafer cleaning apparatus using ultra/mega sonic device;

FIGS. 18A-18C depict another exemplary wafer cleaning method;

FIG. 19 depicts another exemplary wafer cleaning method;

FIG. 20A to FIG. 20D depict bubbles in the status of below the saturation point in the feature of vias or trenches;

FIG. 20E to FIG. 20H depict the size of bubbles expanded by the ultra/mega sonic device to result in the ratio R of total bubbles volume V_{B} to the volume of via, trench or recessed space V_{VTR} being closed to or above the saturation point;

FIG. 20I and FIG. 20J depict the size of bubbles expanded by the ultra/mega sonic device within a limitation to result in the ratio R of total bubbles volume V_{B} to the volume of via, trench or recessed space V_{VTR} being much below the saturation point;

FIGS. 21A-21D depict an exemplary substrate cleaning method;

FIGS. 22A-22D depict another exemplary substrate cleaning method;

FIGS. 23A-23C depict another exemplary substrate cleaning method;

FIGS. 24A-24E depict another exemplary substrate cleaning method;

FIG. 25 depicts a relationship between the number of bubbles and gas concentration in the cleaning liquid;

FIG. 26 depicts another exemplary substrate cleaning apparatus including a de-bubble device; and

FIGS. 27A-27B depict another exemplary substrate cleaning method.

### DETAILED DESCRIPTION

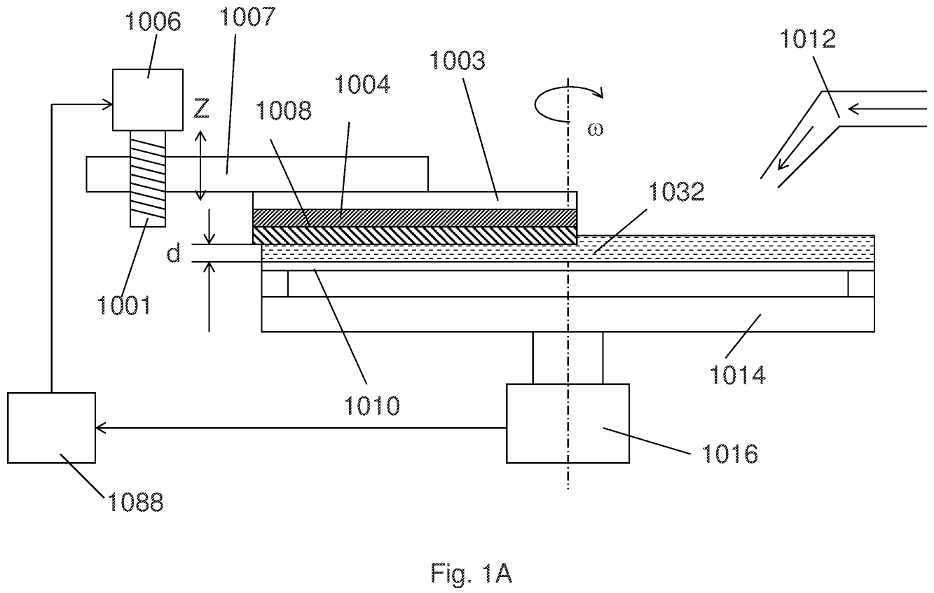

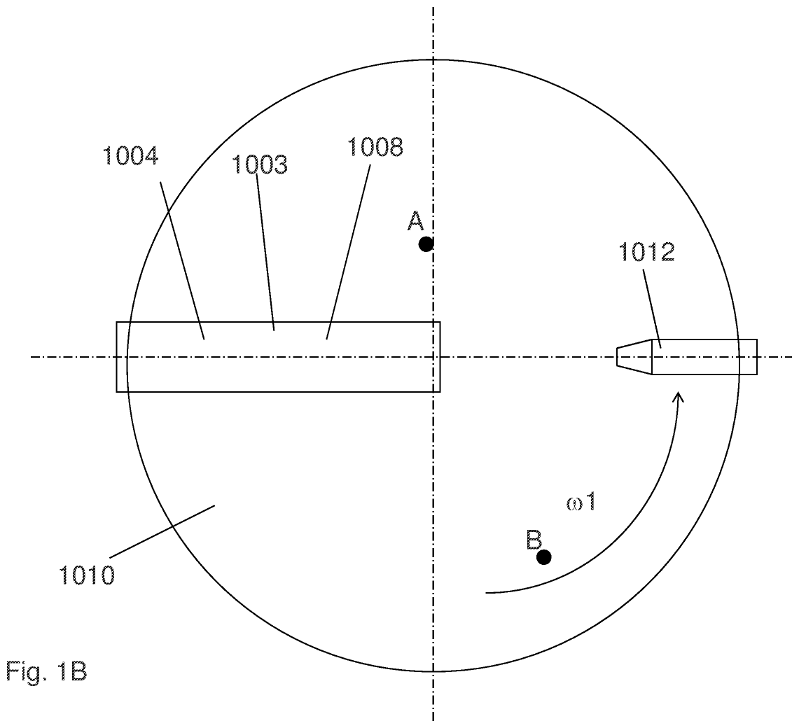

FIGS. 1A to 1B show a wafer cleaning apparatus using a ultra/mega sonic device. The wafer cleaning apparatus consists of wafer 1010, wafer chuck 1014 being rotated by rotation driving mechanism 1016, nozzle 1012 delivering cleaning chemicals or de-ionized water 1032, and ultra/mega sonic device 1003 and ultra/mega sonic power supply. The ultra/mega sonic device 1003 further consists of piezoelectric transducer 1004 acoustically coupled to resonator 1008. Transducer 1004 is electrically excited such that it vibrates and the resonator 1008 transmits high frequency sound energy into liquid. The bubble cavitation generated by the ultra/mega sonic energy oscillates particles on wafer 1010. Contaminants are thus vibrated away from the surfaces of the wafer 1010, and removed from the surfaces through the flowing liquid 1032 supplied by nozzle 1012.

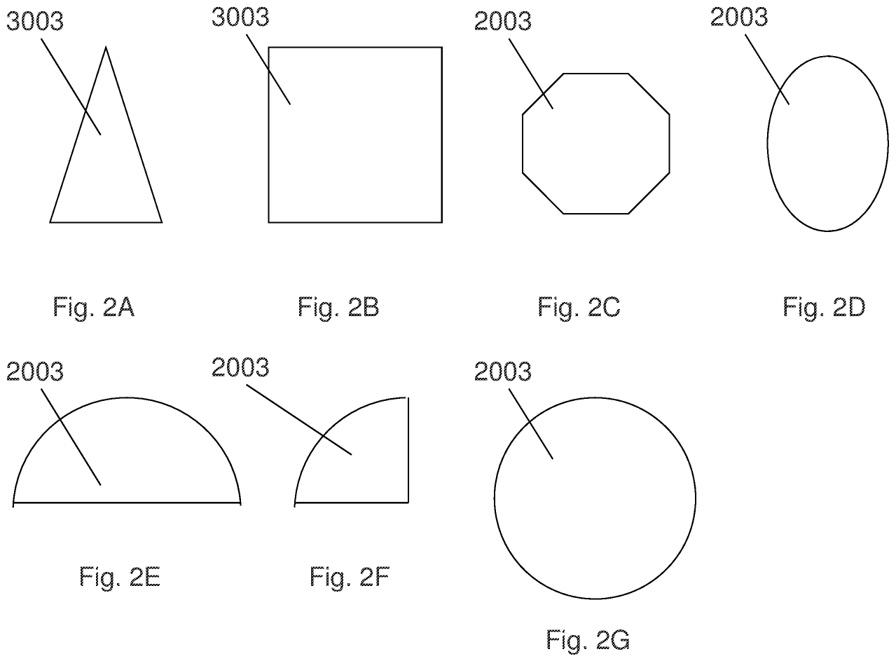

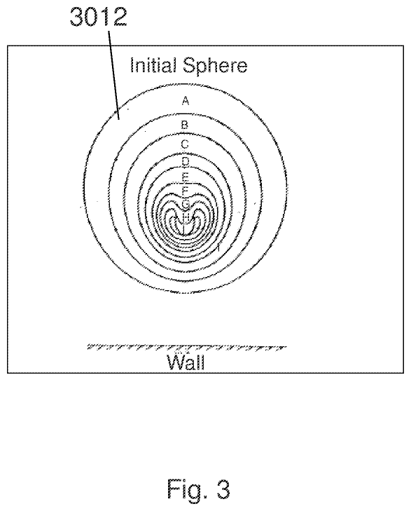

FIGS. 2A to 2G show top view of ultra/mega sonic devices according to the present invention. Ultra/mega sonic device 1003 shown in FIG. 1 can be replaced by different shape of ultra/mega sonic devices 3003, i.e. triangle or pie shape as shown in FIG. 2A, rectangle as shown in FIG. 2B, octagon as shown in FIG. 2C, elliptical as shown in FIG. 2D, half circle as shown in FIG. 2E, quarter circle as shown in FIG. 2F, and circle as shown in FIG. 2G.

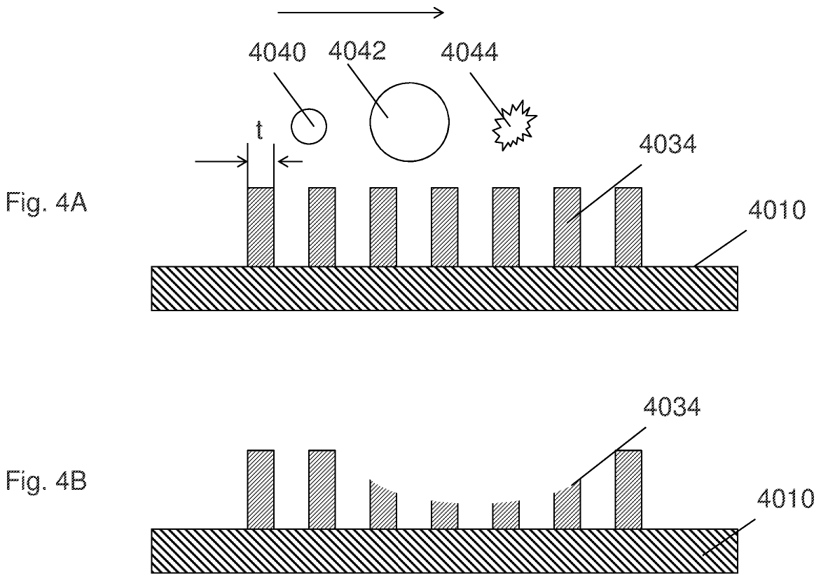

FIG. 3 shows a bubble cavitation during compression phase. The shape of bubbler is gradually compressed from a spherical shape A to an apple shape G, finally the bubble reaches to an implosion status I and forms a micro jet. As shown in FIGS. 4A and 4B, the micro jet is very violent (can reaches a few thousands atmospheric pressures and a few thousands ° C.), which can damage the fine patterned structure 4034 on the semiconductor wafer 4010, especially when the feature size t shrinks to 70 nm and smaller.

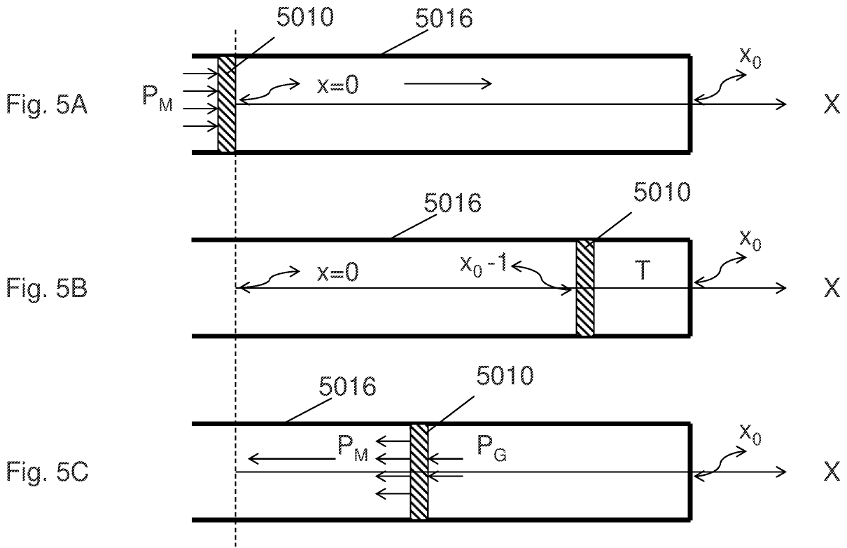

FIGS. 5A to 5C show simplified model of bubble cavitation according to the present invention. As sonic positive pressure acting on the bubble, the bubble reduces its volume. During this volume shrinking process, the sonic pressure P_{M} did a work to the bubble, and the mechanical work converts to thermal energy inside the bubble, therefore temperature of gas and/or vapor inside bubble increases.

The idea gas equation can be expressed as follows:

p₀v₀/T₀=pv/T (1),

where, p₀ is pressure inside bubbler before compression, v₀ initial volume of bubble before compression, T₀ temperature of gas inside bubbler before compression, p is pressure inside bubbler in compression, v volume of bubble in compression, T temperature of gas inside bubbler in compression.

In order to simplify the calculation, assuming the temperature of gas is no change during the compression or compression is very slow and temperature increase is cancelled by liquid surrounding the bubble. So that the mechanical work wₘ did by sonic pressure P_{M} during one time of bubbler compression (from volume N unit to volume 1 unit or compression ratio=N) can be expressed as follows:

$${w}_{m} = {\int }_{0}^{x 0 - 1} pSdx = {\int }_{0}^{x 0 - 1} ( S ( {x}_{0} {p}_{0} ) / ( {x}_{0} - x ) ) d x = S {x}_{0} {p}_{0} {\int }_{0}^{x 0 - 1} d x / ( {x}_{0} - x ) = - S {x}_{0} {p}_{0} ln ( {x}_{{0}^{-}} x ) {\vert}_{0}^{x 0 - 1} = S {x}_{0} {p}_{0} ln ( {x}_{0} ) \qquad ( 2 )$$

Where, S is area of cross section of cylinder, x₀ the length of the cylinder, p₀ pressure of gas inside cylinder before compression. The equation (2) does not consider the factor of temperature increase during the compression, so that the actual pressure inside bubble will be higher due to temperature increase. Therefore the actual mechanical work conducted by sonic pressure will be larger than that calculated by equation (2).
If assuming all mechanical work did by sonic pressure is partially converted to thermal energy and partially converted mechanical energy of high pressure gas and vapor inside bubble, and such thermal energy is fully contributed to temperature increase of gas inside of bubbler (no energy transferred to liquid molecules surrounding the bubble), and assuming the mass of gas inside bubble staying constant before and after compression, then temperature increase ΔT after one time of compression of bubble can be expressed in the following formula:

ΔT=Q/(mc)=βwₘ/(mc)=βSx₀p₀ ln(x₀)/(mc) (3)

where, Q is thermal energy converted from mechanical work, β ratio of thermal energy to total mechanical works did by sonic pressure, m mass of gas inside the bubble, c gas specific heat coefficient. Substituting β=0.65, S=1E-12 m², x₀=1000 μm=1E-3 m (compression ratio N=1000), p₀=1 kg/cm²=1E4 kg/m², m=8.9E-17 kg for hydrogen gas, c=9.9E3 J/(kg ° C.) into equation (3), then ΔT=50.9° C.
The temperature T₁ of gas inside bubbler after first time compression can be calculated as

T₁=T₀+ΔT=20° C.+50.9° C.=70.9° C. (4)

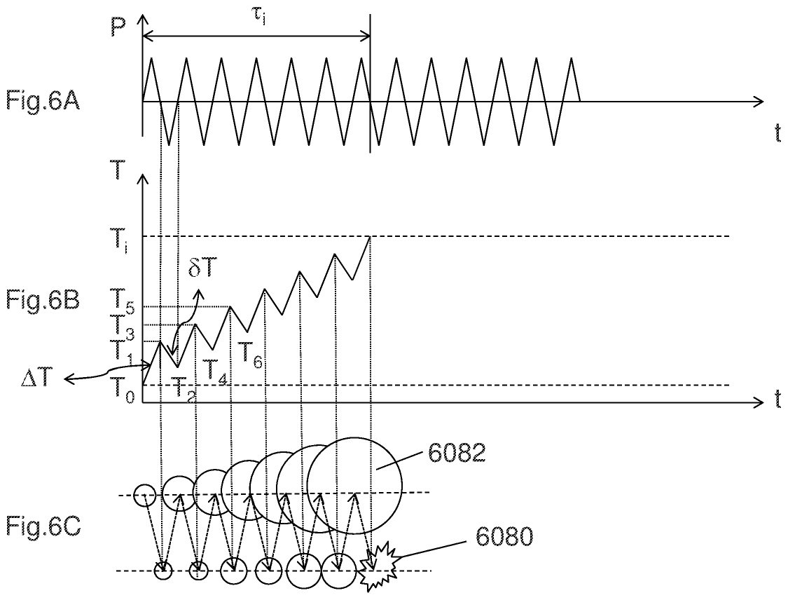

When the bubble reaches the minimum size of 1 micron as shown in FIG. 5B. At such a high temperature, of cause some liquid molecules surrounding bubble will evaporate. After then, the sonic pressure become negative and bubble starts to increase its size. In this reverse process, the hot gas and vapor with pressure P_{G} will do work to the surrounding liquid surface. At the same time, the sonic pressure P_{M} is pulling bubble to expansion direction as shown in FIG. 5C, therefore the negative sonic pressure P_{M} also do partial work to the surrounding liquid too. As the results of the joint efforts, the thermal energy inside bubble cannot be fully released or converted to mechanical energy, therefore the temperature of gas inside bubble cannot cool down to original gas temperature T₀ or the liquid temperature. After the first cycle of cavitation finishes, the temperature T₂ of gas in bubble will be somewhere between T₀ and T₁ as shown in FIG. 6B. Or T₂ can be expressed as

T₂=T1−δT=T₀+ΔT−δT (5)

Where δT is temperature decrease after one time of expansion of the bubble, and δT is smaller than ΔT.

When the second cycle of bubble cavitation reaches the minimum bubble size, the temperature T3 of gas and or vapor inside bubbler will be

T3=T2+ΔT=T₀+ΔT−δT+ΔT=T₀+2ΔT−δT (6)

When the second cycle of bubble cavitation finishes, the temperature T4 of gas and/or vapor inside bubbler will be

T4=T3−δT=T₀+2ΔT−δT−δT=T₀+2ΔT−2δT (7)

Similarly, when the nth cycle of bubble cavitation reaches the minimum bubble size, the temperature T₂ₙ₋₁ of gas and or vapor inside bubbler will be

T₂ₙ₋₁=T₀+nΔT−(n−1)δT (8)

When the nth cycle of bubble cavitation finishes, the temperature T₂ₙ of gas and/or vapor inside bubbler will be

T₂ₙ=T₀+nΔT−nδT=T₀+n(ΔT−δT) (9)

As cycle number n of bubble cavitation increase, the temperature of gas and vapor will increase, therefore more molecules on bubble surface will evaporate into inside of bubble 6082 and size of bubble 6082 will increase too, as shown in FIG. 6C. Finally the temperature inside bubble during compression will reach implosion temperature Tᵢ (normally Tᵢ is as high as a few thousands ° C.), and violent micro jet 6080 forms as shown in FIG. 6C.

From equation (8), implosion cycle number n₁ can be written as following:

nᵢ=(Tᵢ−T₀−ΔT)/(ΔT−δT)+1 (10)

From equation (10), implosion time can be written as following:

$$\begin{matrix}{τ}_{i} = {n}_{i} {t}_{1} = {t}_{1} ( ( {T}_{i} - {T}_{0} - Δ T ) / ( Δ T - δ T ) + 1 ) \\ = {n}_{i} / {f}_{1} = ( ( {T}_{i} - {T}_{0} - Δ T ) / ( Δ T - δ T ) + 1 ) / {f}_{1}\end{matrix} \qquad ( 11 )$$

Where, t₁ is cycle period, and f₁ frequency of ultra/mega sonic wave.

According to formulas (10) and (11), implosion cycle number nᵢ and implosion time τᵢ can be calculated. Table 1 shows calculated relationships among implosion cycle number nᵢ, implosion time τᵢ and (ΔT−δT), assuming Ti=3000° C., ΔT=50.9° C., T₀=20° C., f₁=500 KHz, f₁=1 MHz, and f₁=2 MHz.

TABLE 1

| ΔT-δT (° C.) | 0.1 | 1 | 10 | 30 | 50 |
|---|---|---|---|---|---|
| nᵢ | 29018 | 2903 | 291 | 98 | 59 |
| τᵢ (ms) | 58.036 | 5.806 | 0.582 | 0.196 | 0.118 |
| f₁ = 500 KHz | | | | | |
| τᵢ (ms) | 29.018 | 2.903 | 0.291 | 0.098 | 0.059 |
| f₁ = 1 MHz | | | | | |
| τᵢ (ms) | 14.509 | 1.451 | 0.145 | 0.049 | 0.029 |
| f₁ = 2 MHz | | | | | |

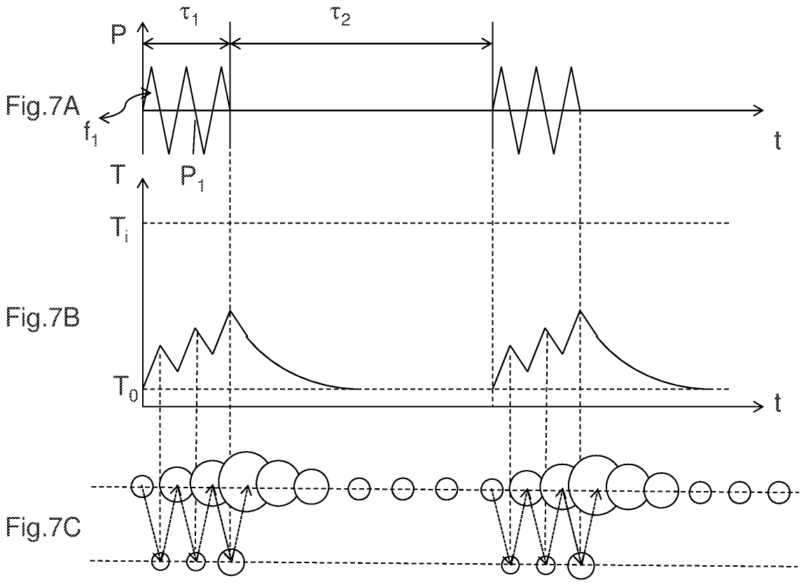

In order to avoid damage to patterned structure on wafer, a stable cavitation must be maintained, and the bubble implosion or micro jet must be avoided. FIGS. 7A to 7C shows a method to achieve a damage free ultra or mega-sonic cleaning on a wafer with patterned structure by maintaining a stable bubble cavitation according to the present invention. FIG. 7A shows waveform of power supply outputs, and FIG. 7B shows the temperature curve corresponding to each cycle of cavitation, and FIG. 7C shows the bubble size expansion during each cycle of cavitation. Operation process steps to avoid bubble implosion according to the present invention are disclosed as follows:

Step 1: Put ultra/mega sonic device adjacent to surface of wafer or substrate set on a chuck or tank;

Step 2: Fill chemical liquid or gas (hydrogen, nitrogen, oxygen, or CO₂) doped water between wafer and the ultra/mega sonic device;

Step 3: Rotate chuck or oscillate wafer;

Step 4: Set power supply at frequency f₁ and power P₁;

Step 5: Before temperature of gas and vapor inside bubble reaches implosion temperature Tᵢ, (or time reach τ₁<τᵢ as being calculated by equation (11)), set power supply output to zero watts, therefore the temperature of gas inside bubble start to cool down since the temperature of liquid or water is much lower than gas temperature.

Step 6: After temperature of gas inside bubble decreases to room temperature T₀ or time (zero power time) reaches τ₂, set power supply at frequency f₁ and power P₁ again.

Step 7: repeat Step 1 to Step 6 until wafer is cleaned.

In step 5, the time τ₁ must be shorter than τᵢ in order to avoid bubble implosion, and τᵢ can be calculated by using equation (11).

In step 6, the temperature of gas inside bubble is not necessary to be cooled down to room temperature or liquid temperature; it can be certain temperature above room temperature or liquid temperature, but better to be significantly lower than implosion temperature Tᵢ.

According to equations 8 and 9, if (ΔT−δT) can be known, the τᵢ can be calculated. But in general, (ΔT−δT) is not easy to be calculated or measured directly. The following method can determine the implosion time experimentally.

Step 1: Based on Table 1, choosing 5 different time τ₁ as design of experiment (DOE) conditions,

Step 2: choose time τ₂ at least 10 times of τ₁, better to be 100 times of τ₁ at the first screen test

Step 3: fix certain power P₀ to run above five conditions cleaning on specific patterned structure wafer separately. Here, P₀ is the power at which the patterned structures on wafer will be surely damaged when running on continuous mode (non-pulse mode).

Step 4: Inspect the damage status of above five wafers by SEMS or wafer pattern damage review tool such as AMAT SEM vision or Hitachi IS3000, and then the implosion time τᵢ can be located in certain range.

Step 1 to 4 can be repeated again to narrow down the range of implosion time τᵢ. After knowing the implosion time τᵢ, the time τ₁ can be set at a value smaller than 0.5τᵢ for safety margin. One example of experimental data is described as following.

The patterned structures are 55 nm poly-silicon gate lines. Ultra/mega sonic wave frequency was 1 MHz, and ultra/mega-sonic device manufactured by Prosys was used and operated in a gap oscillation mode (disclosed by PCT/CN2008/073471) for achieving better uniform energy dose within wafer and wafer to wafer. Other experimental parameters and final pattern damage data are summarized in Table 2 as follows:

TABLE 2

| | | | Power | | | | Number |
|---|---|---|---|---|---|---|---|
| | CO₂ | Process | Density | | | | of |
| Wafer | conc. | Time | (Watts/ | Cycle | τ1 | τ2 | Damage |
| ID | (18 μs/cm) | (sec) | cm2) | Number | (ms) | (ms) | Sites |
| #1 | 18 | 60 | 0.1 | 2000 | 2 | 18 | 1216 |
| #2 | 18 | 60 | 0.1 | 100 | 0.1 | 0.9 | 0 |

It was clear that the τ₁=2 ms (or 2000 cycle number) introduced as many as 1216 damage sites to patterned structure with 55 nm feature size, but that the τ₁=0.1 ms (or 100 cycle number) introduced zero (0) damage sites to patterned structure with 55 nm feature size. So that the τᵢ is some number between 0.1 ms and 2 ms, more detail tests need to be done to narrow its range. Obviously, the cycle number related to ultra or mega sonic power density and frequency, the larger the power density, the less the cycle number; and the lower the frequency, the less the cycle number. From above experimental results, we can predict that the damage-free cycle number should be smaller than 2,000, assuming the power density of ultra or mega sonic wave is larger than 0.1 wattsorcm², and frequency of ultra or mega sonic wave is equal to or less than 1 MHz. If the frequency increases to a range larger than 1 MHz or power density is less than 0.1 watts/cm², it can be predicted that the cycle number will increase.

After knowing the time τ₁, then the time τ₂ can be shorten based on similar DEO method described above, i.e. fix time τ₁, gradually shorten the time τ₂ to run DOE till damage on patterned structure being observed. As the time τ₂ is shorten, the temperature of gas and or vapor inside bubbler cannot be cooled down enough, which will gradually shift average temperature of gas and vapor inside bubbler up, eventually it will trigger implosion of bubble. This trigger time is called critical cooling time. After knowing critical cooling time τ_{c}, the time τ₂ can be set at value larger than 2τ_{c} for the same reason to gain safety margin.

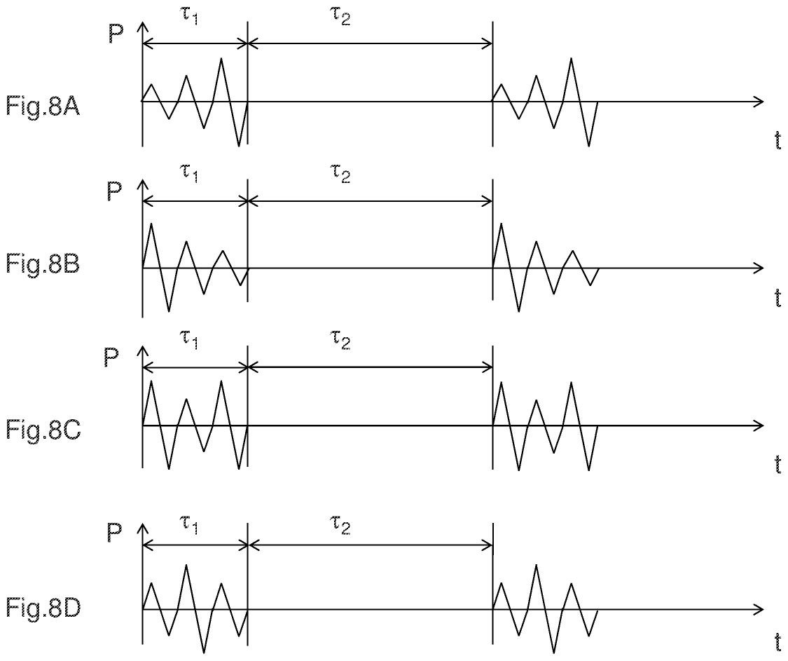

FIGS. 8A to 8D show another embodiment of wafer cleaning method using a ultra/mega sonic device according to the present invention. The method is similar to that shown in FIG. 7A, except in step 4 setting ultra/mega sonic power supply at frequency f₁ and power with changing amplitude of waveform. FIG. 8A shows another cleaning method of setting ultra/mega sonic power at frequency f₁ and power with increasing amplitude of waveform in step 4. FIG. 8B shows another cleaning method of setting ultra/mega sonic power supply at frequency f₁ and power with decreasing amplitude of waveform in step 4. FIG. 8C shows another cleaning method of setting ultra/mega sonic power supply at frequency f₁ and power with decreasing first and increasing later amplitude of waveform in step 4. FIG. 8D shows further another cleaning method of setting ultra/mega sonic power at frequency f₁ and power with increasing first and decreasing later amplitude of waveform in step 4.

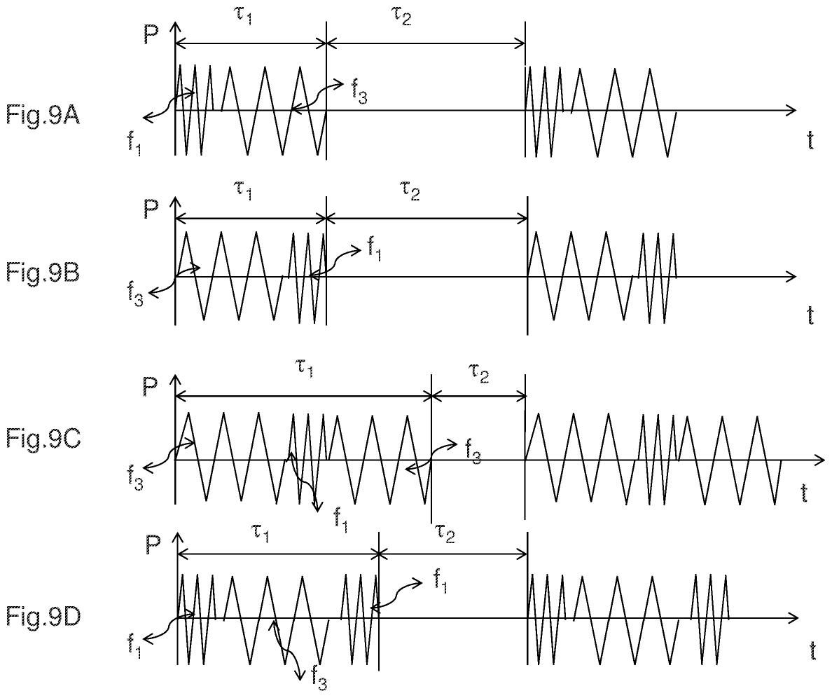

FIGS. 9A to 9D show another embodiment of wafer cleaning method using a ultra/mega sonic device according to the present invention. The method is similar to that shown in FIG. 7A, except in step 4 setting ultra/mega sonic power supply at changing frequency. FIG. 9A shows another cleaning method of setting ultra/mega sonic power supply at frequency f₁ first then frequency f₃ later, f₁ is higher than f₃ in step 4. FIG. 9B shows another cleaning method of setting ultra/mega sonic power supply at frequency f₃ first then frequency f₁ later, f₁ is higher than f₃ in step 4. FIG. 9C shows another cleaning method of setting ultra/mega sonic power supply at frequency f₃ first, frequency f₁ later and f₃ last, f₁ is higher than f₃ in step 4. FIG. 9D shows another cleaning method of setting ultra/mega sonic power supply at frequency f₁ first, frequency f₃ later and f₁ last, f₁ is higher than f₃ in step 4.

Similar to method shown in FIG. 9C, the ultra/mega sonic power can be set at frequency f₁ first, at frequency f₃ later and at frequency f₄ at last in step 4, where f₄ is smaller than f₃, and f₃ is smaller than f₁.

Again similar to method shown in FIG. 9C, the ultra/mega sonic power can be set at frequency f₄ first, at frequency f₃ later and at frequency f₁ at last in step 4, where f₄ is smaller than f₃, and f₃ is smaller than f₁

Again similar to method shown in FIG. 9C, the ultra/mega sonic power can be set at frequency f₁ first, at frequency f₄ later and at frequency f₃ at last in step 4, where f₄ is smaller than f₃, and f₃ is smaller than f₁.

Again similar to method shown in FIG. 9C, the ultra/mega sonic power can be set at frequency f₃ first, at frequency f₄ later and at frequency f₁ at last in step 4, where f₄ is smaller than f₃, and f₃ is smaller than f₁.

Again similar to method shown in FIG. 9C, the ultra/mega sonic power can be set at frequency f₃ first, at frequency f₁ later and at frequency f₄ at last in step 4, where f₄ is smaller than f₃, and f₃ is smaller than f₁.

Again similar to method shown in FIG. 9C, the ultra/mega sonic power can be set at frequency f₄ first, at frequency f₁ later and at frequency f₃ at last in step 4, where f₄ is smaller than f₃, and f₃ is smaller than f₁.

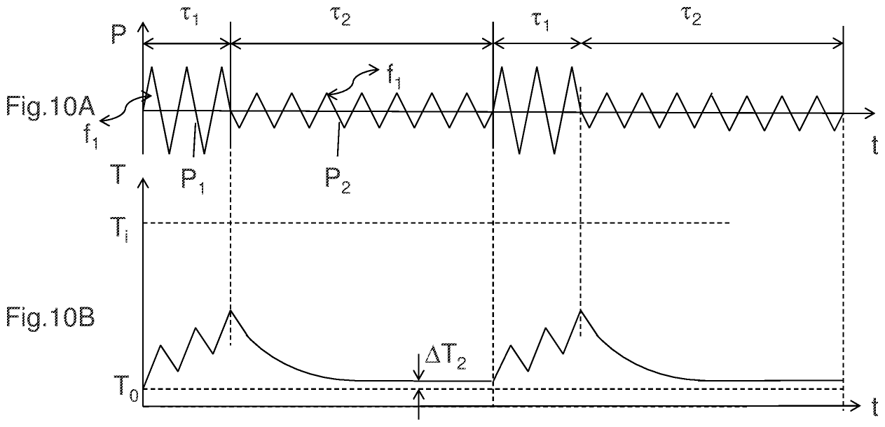

FIGS. 10A to 10B show another method to achieve a damage free ultra/mega-sonic cleaning on a wafer with patterned structure by maintaining a stable bubble cavitation in according to the present invention. FIG. 10A shows waveform of power supply outputs, and FIG. 10B shows the temperature curve corresponding to each cycle of cavitation. Operation process steps according to the present invention are disclosed as follows:

Step 1: Put ultra/mega sonic device adjacent to surface of wafer or substrate set on a chuck or tank;

Step 2: Fill chemical liquid or gas doped water between wafer and the ultra/mega sonic device;

Step 3: Rotate chuck or oscillate wafer;

Step 4: Set power supply at frequency f₁ and power P₁;

Step 5: Before temperature of gas and vapor inside bubble reaches implosion temperature Tᵢ, (total time τ₁ elapses), set power supply output at frequency f₁ and power P₂, and P₂ is smaller than P₁. Therefore the temperature of gas inside bubble start to cool down since the temperature of liquid or water is much lower than gas temperature.

Step 6: After temperature of gas inside bubble decreases to certain temperature close to room temperature T₀ or time (zero power time) reach τ₂, set power supply at frequency f₁ and power P₁ again.

Step 7: repeat Step 1 to Step 6 until wafer is cleaned.

In step 6, the temperature of gas inside bubble can not be cooled down to room temperature due to power P₂, there should be a temperature difference ΔT₂ existing in later stage of τ₂ time zone, as shown in FIG. 10B.

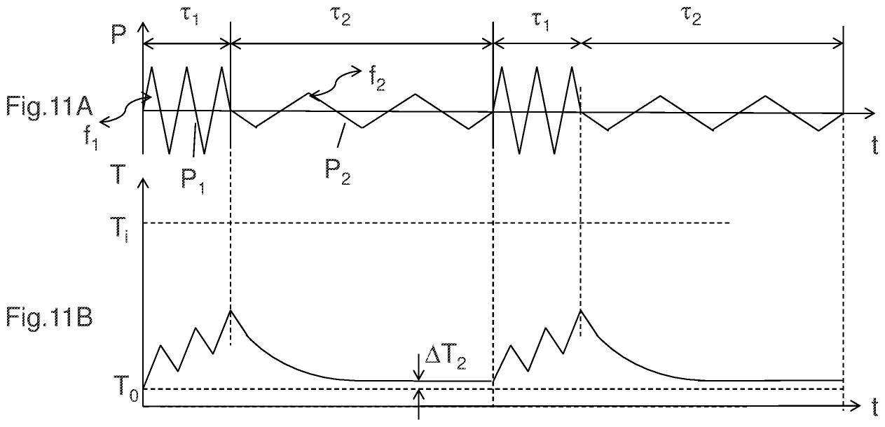

FIGS. 11A to 11B show another embodiment of wafer cleaning method using a ultra/mega sonic device according to the present invention. The method is similar to that shown in FIG. 10A, except in step 5 setting ultra/mega sonic power at frequency f₂ and power P₂, where f₂ is lower than f₁ and P₂ is less than P₁. Since f₂ is lower than f₁, the temperature of gas or vapor inside bubble increasing faster, therefore the P2 should be set significantly less than P1, better to be 5 or 10 times less in order to reduce temperature of gas and or vapor inside bubble.

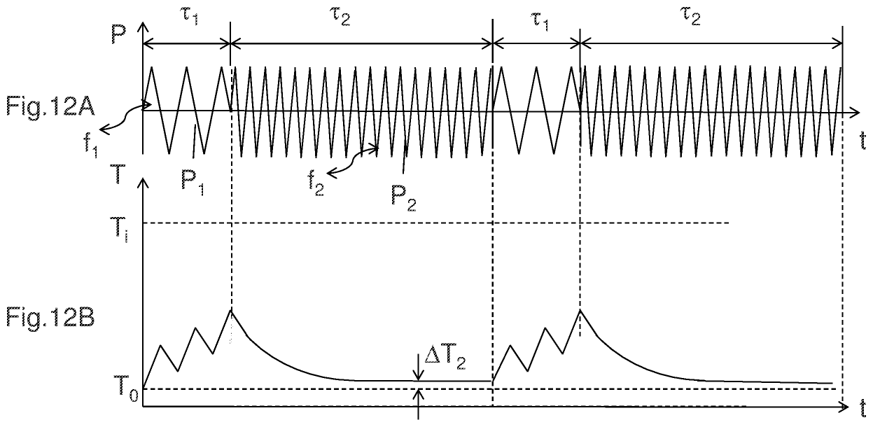

FIGS. 12A to 12B show another embodiment of wafer cleaning method using a ultra/mega sonic device according to the present invention. The method is similar to that shown in FIG. 10A, except in step 5 setting ultra/mega sonic power at frequency f₂ and power P₂, where f₂ is higher than f₁, and P₂ is equal to P₁.

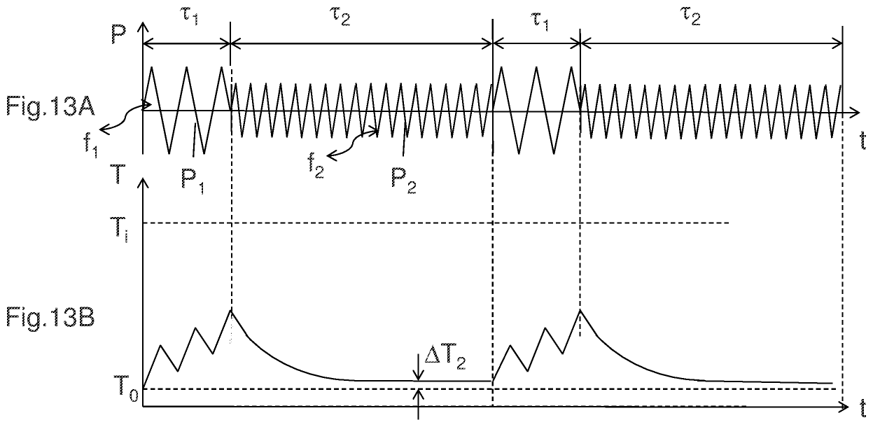

FIGS. 13A to 13B show another embodiment of wafer cleaning method using a ultra/mega sonic device according to the present invention. The method is similar to that shown in FIG. 10A, except in step 5 setting ultra/mega sonic power at frequency f₂ and power P₂, where f₂ is higher than f₁, and P₂ is less than P₁.

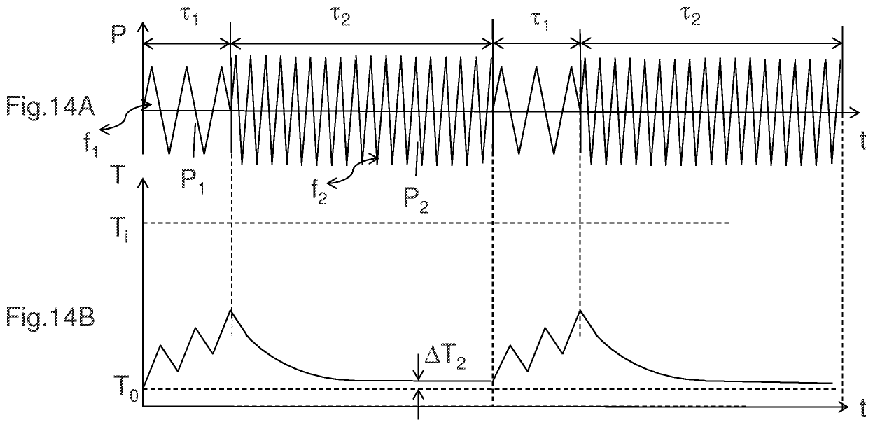

FIGS. 14A-14B shows another embodiment of wafer cleaning method using a ultra/mega sonic device according to the present invention. The method is similar to that shown in FIG. 10A, except in step 5 setting ultra/mega sonic power at frequency f₂ and power P₂, where f₂ is higher than f₁, and P₂ is higher than P₁. Since f₂ is higher than f₁, the temperature of gas or vapor inside bubble increasing slower, therefore the P2 can be slightly higher than P1, but must make sure the temperature of gas and vapor inside bubbler decreases in time zone τ₂ comparing to temperature zone τᵢ, as shown in FIG. 14B

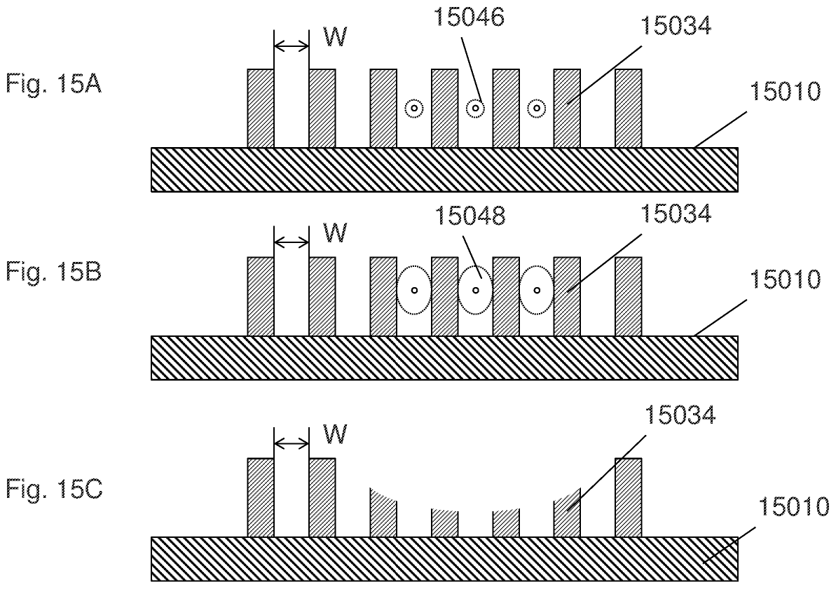

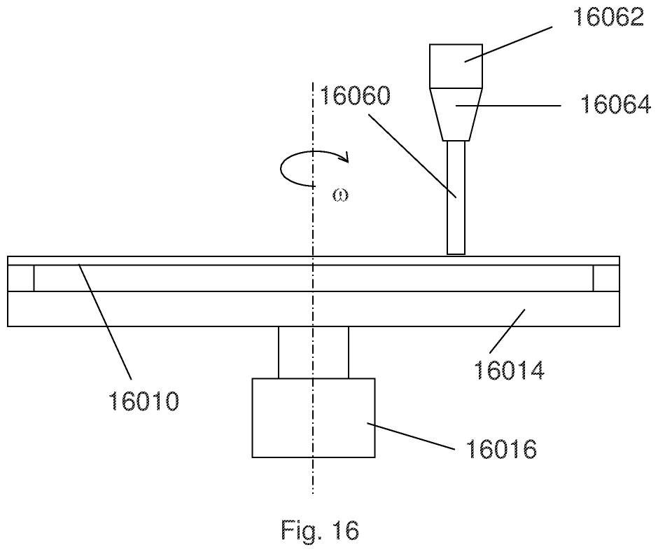

FIGS. 4A and 4B show that patterned structure is damaged by the violent micro jet. FIGS. 15A and 15B show that the stable cavitation can also damage the patterned structure on wafer. As bubble cavitation continues, the temperature of gas and vapor inside bubble increases, therefore size of bubble 15046 also increases as shown in FIG. 15A. When size of bubble 15048 becomes larger than dimension of space W in patterned structure as shown in FIG. 15B, the expansion force of bubble cavitation can damage the patterned structure 15034 as shown in FIG. 15C. Another cleaning method according to the present invention are disclosed as follows:

Step 1: Put ultra/mega sonic device adjacent to surface of wafer or substrate set on a chuck or tank;

Step 2: Fill chemical liquid or gas doped water between wafer and the ultra/mega sonic device;

Step 3: Rotate chuck or oscillate wafer;

Step 4: Set power supply at frequency f₁ and power P₁;

Step 5: Before size of bubble reaches the same dimension of space W in patterned structures (time τ₁ elapse), set power supply output to zero watts, therefore the temperature of gas inside bubble starts to cool down since the temperature of liquid or water is much lower than gas temperature;

Step 6: After temperature of gas inside bubble continues to reduce (either it reaches room temperature T₀ or time (zero power time) reach τ₂, set power supply at frequency f₁ power P₁ again;

Step 7: repeat Step 1 to Step 6 until wafer is cleaned;

In step 6, the temperature of gas inside bubble is not necessary to be cooled down to room temperature, it can be any temperature, but better to be significantly lower than implosion temperature Tᵢ. In the step 5, bubble size can be slightly larger than dimension of patterned structures as long as bubble expansion force does not break or damage the patterned structure. The time τ₁ can be determined experimentally by using the following method:

Step 1: Similar to Table 1, choosing 5 different time τ₁ as design of experiment (DOE) conditions,

Step 2: choose time τ₂ at least 10 times of τ₁, better to be 100 times of τ₁ at the first screen test

Step 3: fix certain power P₀ to run above five conditions cleaning on specific patterned structure wafer separately. Here, P₀ is the power at which the patterned structures on wafer will be surely damaged when running on continuous mode (non-pulse mode).

Step 4: Inspect the damage status of above five wafers by SEMS or wafer pattern damage review tool such as AMAT SEM vision or Hitachi IS3000, and then the damage time τᵢ can be located in certain range.

Step 1 to 4 can be repeated again to narrow down the range of damage time τ_{d}. After knowing the damage time τ_{d}, the time τ₁ can be set at a value smaller than 0.5 τ_{d} for safety margin.

All cleaning methods described from FIG. 7 to FIG. 14 can be applied in or combined with the method described in FIG. 15.

FIG. 16 shows a wafer cleaning apparatus using a ultra/mega sonic device. The wafer cleaning apparatus consists of wafer 16010, wafer chuck 16014 being rotated by rotation driving mechanism 16016, nozzle 16064 delivering cleaning chemicals or de-ionized water 16060, ultra/mega sonic device 16062 coupled with nozzle 16064, and ultra/mega sonic power supply. Ultra/mega sonic wave generated by ultra/mega sonic device 16062 is transferred to wafer through chemical or water liquid column 16060. All cleaning methods described from FIG. 7 to FIG. 15 can be used in cleaning apparatus described in FIG. 16.

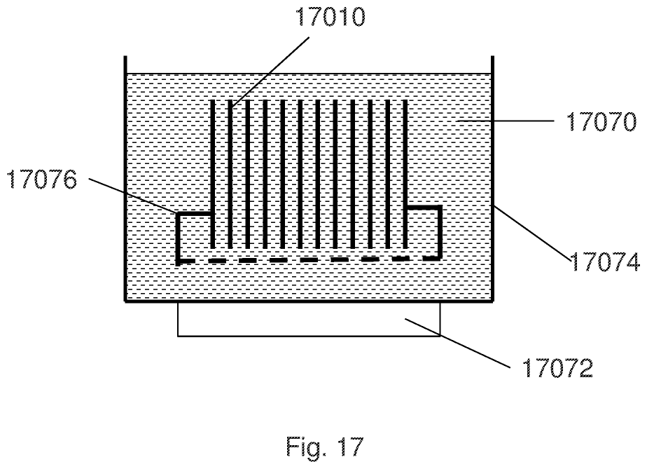

FIG. 17 shows a wafer cleaning apparatus using a ultra/mega sonic device. The wafer cleaning apparatus consists of wafers 17010, a cleaning tank 17074, a wafer cassette 17076 holding the wafers 17010 and being held in the cleaning tank 17074, cleaning chemicals 17070, a ultra/mega sonic device 17072 attached to outside wall of the cleaning tank 17074, and a ultra/mega sonic power supply. At least one inlet fills the cleaning chemicals 17070 into the cleaning tank 17074 to immerse the wafers 17010. All cleaning methods described from FIG. 7 to FIG. 15 can be used in cleaning apparatus described in FIG. 17.

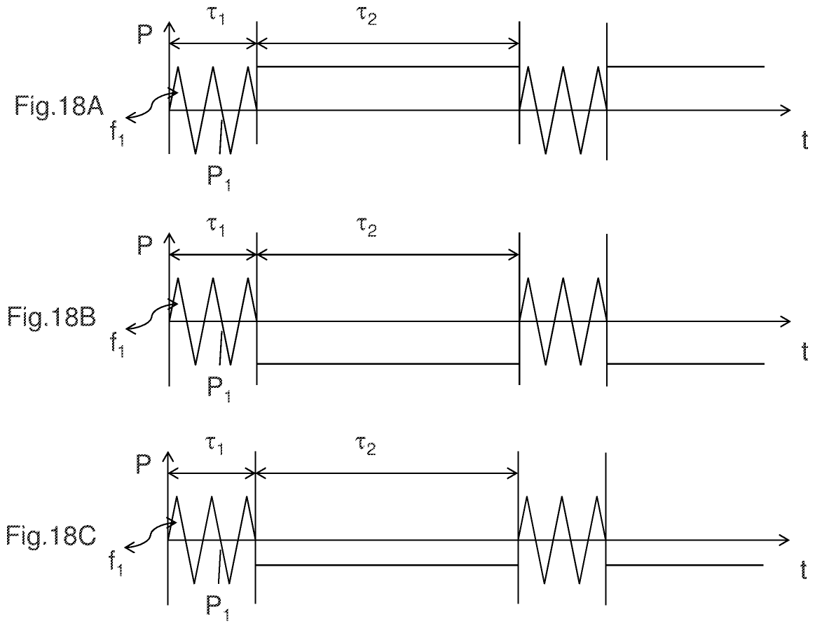

FIGS. 18A to 18C show another embodiment of wafer cleaning method using a ultra/mega sonic device according to the present invention. The method is similar to that shown in FIG. 7A, except in Step 5: Before temperature of gas and vapor inside bubble reaches implosion temperature Tᵢ, (or time reach τ₁<τᵢ as being calculated by equation (11)), set power supply output to a positive value or negative DC value to hold or stop ultra/mega sonic device to vibrate, therefore the temperature of gas inside bubble start to cool down since the temperature of liquid or water is much lower than gas temperature. The positive value of negative value can be bigger, equal to or smaller than power P₁.

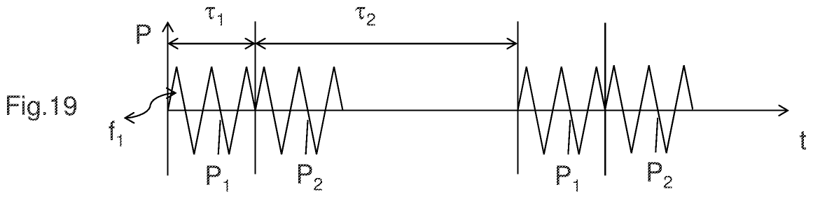

FIG. 19 shows another embodiment of wafer cleaning method using a ultra/mega sonic device according to the present invention. The method is similar to that shown in FIG. 7A, except in Step 5: Before temperature of gas and vapor inside bubble reaches implosion temperature Tᵢ, (or time reach τ₁<τᵢ as being calculated by equation (11)), set power supply output at the frequency same as f₁ with reverse phase to f₁ to quickly stop the cavitation of bubble. Therefore the temperature of gas inside bubble start to cool down since the temperature of liquid or water is much lower than gas temperature. The positive value of negative value can be bigger, equal or less than power P₁. During above operation, the power supply output can be set at a frequency different from frequency f₁ with reverse phase to f₁ in order to quickly stop the cavitation of bubble.

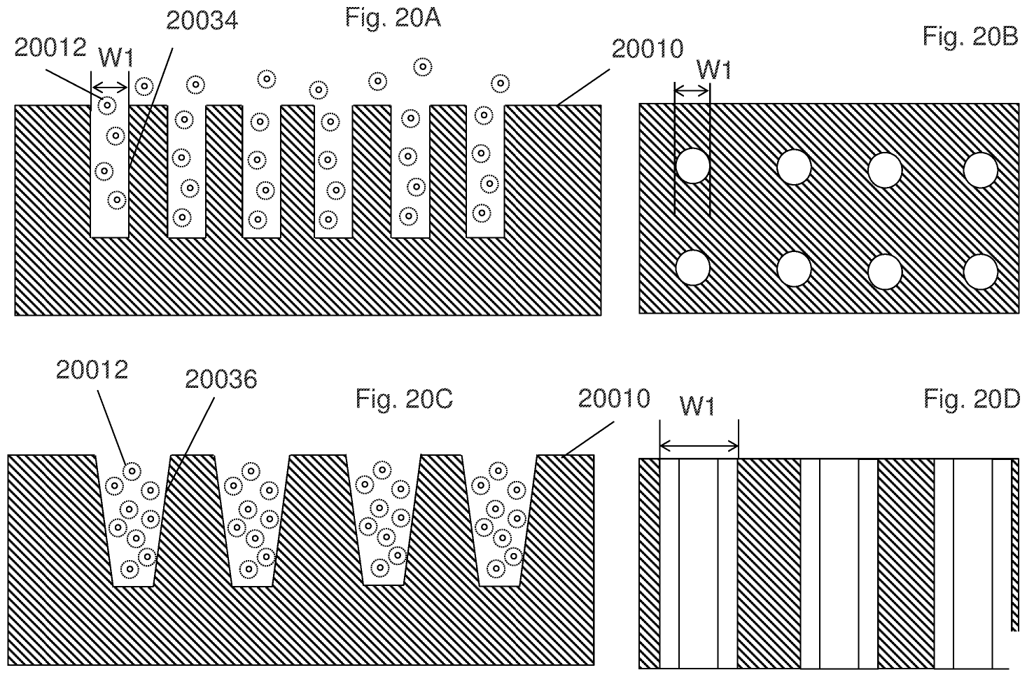

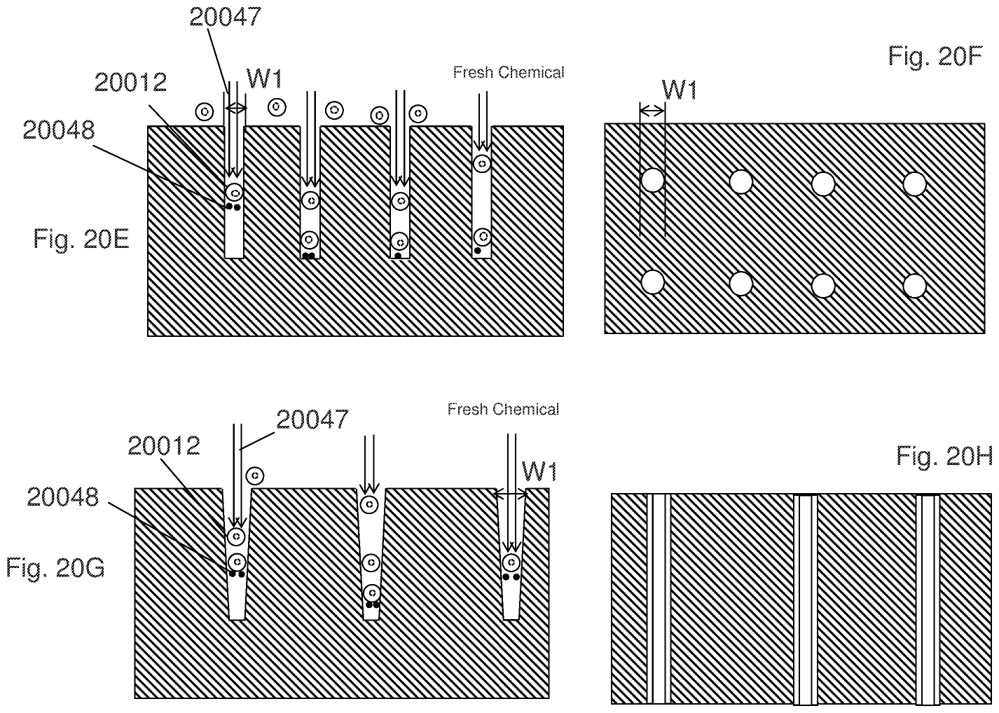

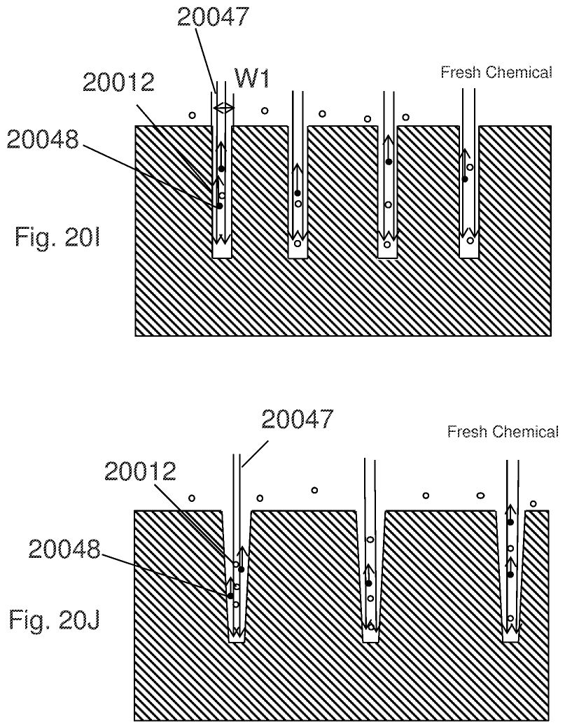

As shown in FIG. 20A to FIG. 20D, the bubbles 20012 are in the status of below the saturation point in the feature of vias 20034 or trenches 20036 on a substrate 20010, so as to increase the fresh chemical exchange in the vias 20034 or trenches 20036 due to the bubble cavitation inside the features and also increase the removal of impurities such as residues and particles from the features. The saturation point R_{S} is defined by the largest amount of bubbles inside the features of vias, trenches or recessed areas. Over the saturation point, the chemical liquid is blocked by the bubbles inside the feature and hardly reaches to the bottom or side walls of the features of vias and trenches, so that the cleaning performance of the chemical liquid is influenced. While below the saturation point, the chemical liquid has enough feasibility inside the features of vias or trenches, and a good cleaning performance is achieved.

Below the saturation point, the ratio R of total bubbles volume V_{B} to the volume of via or trench, or recessed space V_{VTR} is:

R=V_{B}/V_{VTR}<R_{S}

And at or above the saturation point R_{S}, the ratio R of total bubbles volume V_{B} to the volume of via or trench, or recessed space V_{VTR} is:

R=V_{B}/V_{VTR}=R_{S}

The volume of the total bubbles in the features of vias, trenches or recessed space: V_{B}=Nv_{b}

Wherein N is the total bubble numbers in the features and v_{b} is averaged single bubble volume.

As shown in FIG. 20E to FIG. 20H, the size of bubble 20012 expanded by the ultra/mega sonic device is gradually to a certain volume, which results in the ratio R of total bubbles volume V_{B} to the volume of via, trench or recessed space V_{VTR} is closed to or above the saturation point R_{S}. It leads to the expanded bubble 20012 blocking in the vias or trenches, where is the path of chemical exchanges and impurities removal. In the case, the megasonic power cannot thoroughly transfer into the vias or trenches to reach their bottom and sidewall, meanwhile, the particles, residues and other impurities 20048 trapped in the vias or trenches cannot go out efficiently. This case easily occurs as the critical dimension W1 decreasing smaller, and the bubbles in the features of vias and trenches intends to be saturated after being expanded.

As shown in FIG. 20I to FIG. 20J, the size of bubble 20012 is expanded by the ultra/mega sonic device within a limitation, and the ratio R of total bubbles volume V_{B} to the volume of via, trench or recessed space V_{VTR} is much below the saturation point. The fresh chemical 20047 exchanges freely in the vias or trenches due to the bubble cavitation inside the features to achieve a good cleaning performance, meanwhile, the impurities 20048 such as residues and particles go out of the features of vias, trenches and recessed space.

Due to the total bubbles in the features is related to the bubble numbers and the bubble size in the features of vias and treches, the control of bubble size expanded by the cavitation is critical for the cleaning performance in the high aspect ratio features cleaning process.

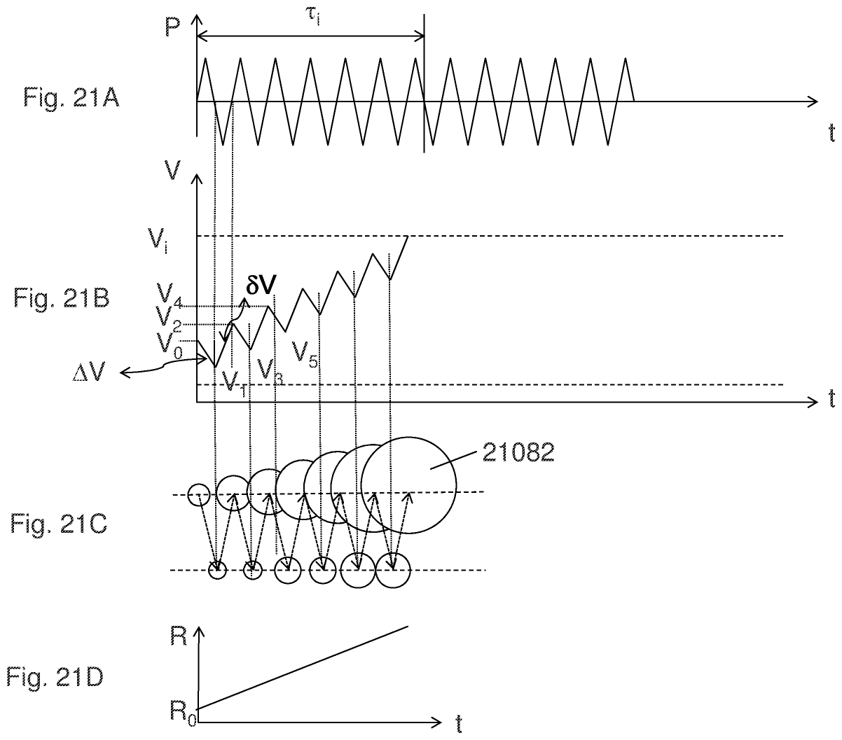

As shown in FIG. 21A to FIG. 21D, after the first cycle of cavitation finishes, the volume of V₁ of gas in bubble is compressed to a minimum size smaller than V₀ during positive sonic power working on it, and the volume of V₂ of gas in bubble will be returned back during the negative sonic power working on it. However, the temperature T₂ in the bubble with the volume of V₂ is higher than the temperature T₀ in the bubble with the volume of V₀, as shown in FIG. 21B, so that the volume of V₂ is bigger than the volume of V₀ due to some liquid molecules surrounding bubble will evaporate under the high temperature. And the volume of V₃ by the second compression of the bubble is somewhere between V₁ and V₂, as shown in FIG. 21B. And V₁, V₂ and V₃ can be expressed as

V₁=V₀−ΔV (12)

V₂=V₁+δV (13)

V₃=V₂−ΔV=V₁+δV−ΔV=V₀−ΔV+δV−ΔV=V₀+δV−2ΔV (14)

Where ΔV is volume compression of bubble after one time of compression due to positive pressure generated by ultra/mega sonic wave, and δV is volume increase of the bubble after one time of expansion due to negative pressure generated by ultra/mega sonic wave, and δV−ΔV is volume increase due to temperature increment ΔT−δT as calculated in equation (5) after one time cycle.

After the second cycle of bubble cavitation, the size of bubble reaches to the larger bubble size during the temperature keeping increasing, the volume of V₄ of gas and or vapor inside bubbler will be

V₄=V₃+δV=V₀+δV−2ΔV+δV=V₀+2(δV−ΔV) (15)

When the third cycle of bubble cavitation, the volume V₅ of gas and/or vapor inside bubbler will be

V₅=V₄−ΔV=V₀+2(δV−ΔV)—ΔV=V₀+2δV−3ΔV (16)

Similarly, when the nth cycle of bubble cavitation reaches the minimum bubble size, the volume V₂ₙ₋₁ of gas and or vapor inside bubbler will be

V₂ₙ₋₁=V₀+(n−1)δV−nΔV=V₀+(n−1)δV−nΔV (17)

When the nth cycle of bubble cavitation finishes, the volume V₂ₙ of gas and/or vapor inside bubbler will be

V₂ₙ=V₀+n(δV−ΔV) (18)

To restrict the volume of bubble into a desired volume Vᵢ, which is a dimension with enough physical feasibility of movement or the bubbles status below the saturation point of cavitation or bubble density, rather than blocking the path of the chemical exchange in the features of vias, trenches or recessed areas, the cycle number nᵢ can be written as following:

nᵢ=(Vᵢ−V₀−ΔV)/(δV−ΔV)+1 (19)

From equation (19), the desired time τᵢ to achieve the Vᵢ can be written as following:

$${τ}_{i} = {n}_{i} {t}_{1} = {t}_{1} ( ( {V}_{i} - {V}_{0} - Δ V ) / ( δ V - Δ V ) + 1 ) = {n}_{i} / {f}_{1} = ( ( {V}_{i} - {V}_{0} - Δ T ) / ( δ V - Δ V ) + 1 ) / {f}_{1} \qquad ( 20 )$$

Where, t₁ is cycle period, and f₁ frequency of ultra/mega sonic wave.

According to formulas (19) and (20), a desired cycle number nᵢ and a time τᵢ to restrict the bubble dimension can be calculated.

It should be pointed that when the cycle number n of bubble cavitation increases, the temperature of gas and liquid (water) vapor inside bubbler will increase, therefore more molecules on bubble surface will evaporate into inside of bubble, therefore the size of bubble 21082 will further increase and be bigger than value calculated by equation (18). In practical operation, since the bubble size will be determined by experimental method to be disclosed later, therefore bubble size impacted by the evaporation of liquid or water for bubble inner surface due to temperature increase will not be theoretically discussed in detail here. As the average single bubble volume keeping increasing, the ratio R of total bubbles volume V_{B} to the volume of via, trench or recessed space V_{VTR} increases from R₀ continuously, as shown in FIG. 21D.

As the bubble volume increases, the diameter of bubble eventually will reach the same size or same order size of feature W1 such as via as shown in FIG. 20E and trench or recessed area as shown in FIG. 20G. Then the bubble inside via and trench will block ultra/mega sonic energy further get into the bottom of via and trench, especially when the aspect ratio (depth/width) is larger than 3 time or more. Therefore contaminations or particles at bottom of such deep via or trench cannot be effectively removed or cleaned.

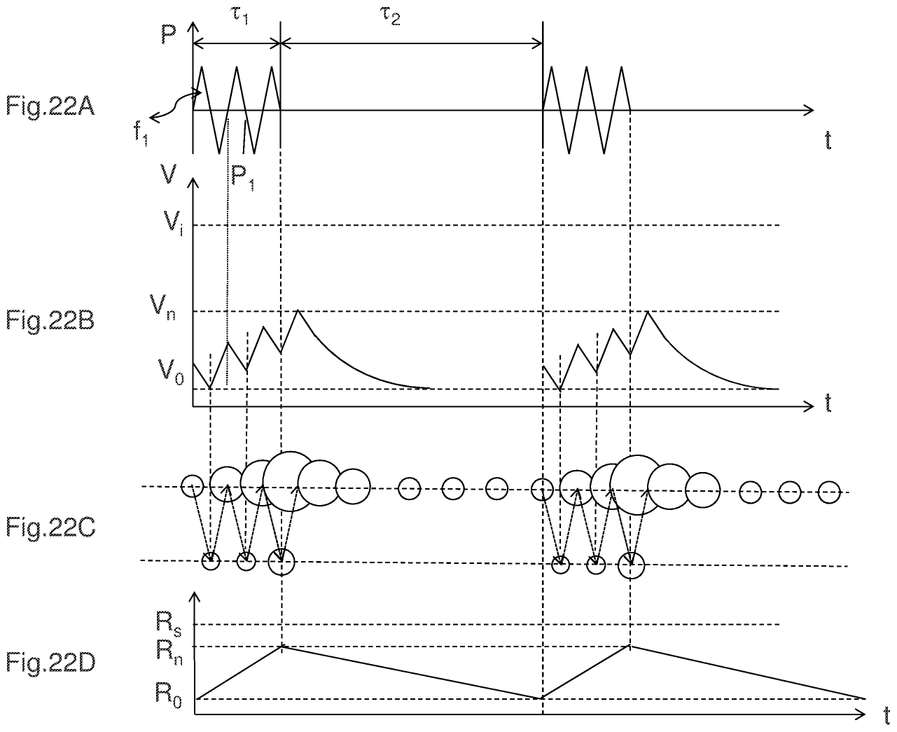

In order to avoid the bubble growth up to a critical dimension to block the path of chemical exchanges in the features of vias or trenches, FIGS. 22A to 22D disclose a method to achieve an effective ultra/mega sonic cleaning on a substrate with high aspect ratio features of vias or trenches by maintaining a restricted size bubble cavitation according to the present invention. FIG. 22A shows waveform of power supply outputs, and FIG. 22B shows the bubble volume curve corresponding to each cycle of cavitation, and FIG. 22C shows the bubble size expansion during each cycle of cavitation, and FIG. 22D shows the curve of the ratio R of total bubbles volume V_{B} to the volume of via, trench or recessed space V_{VTR}. According to

R=V_{B}/V_{VTR}=Nv_{b}/V_{VTR},

the ratio R of total bubbles volume V_{B} to the volume of via, trench or recessed space V_{VTR} increases from R₀ to Rₙ, where the average single bubble volume being expanded by the sonic cavitation after a certain cycle number n, in the time of τ₁. And the Rₙ is controlled below the saturation point R_{S},

Rₙ=V_{B}/V_{VTR}=Nv_{b}/V_{VTR}<Rs.

And the ratio R of total bubbles volume V_{B} to the volume of via, trench or recessed space V_{VTR} decreases from Rₙ to R₀, where the average single bubble volume return to original size in the cooling process in the time of τ₂.

Operation process steps to avoid bubble size growth up according to the present invention are disclosed as follows:

Step 1: Put ultra/mega sonic device adjacent to surface of substrate or substrate set on a chuck or tank;

Step 2: Fill chemical liquid or gas (hydrogen, nitrogen, oxygen, or CO₂) doped water between substrate and the ultra/mega sonic device;

Step 3: Rotate chuck or oscillate substrate;

Step 4: Set power supply at frequency f₁ and power P₁;

Step 5: After the volume of bubble expands to a certain volume Vₙ or diameter w, (or time reach τ₁), set power supply output to zero watts, therefore the volume of gas inside bubble start to shrink down since the temperature of liquid or water cooling down the gas temperature;

Step 6: After the volume of bubble decreases to original volume while the gas temperature decreasing to room temperature T₀ or time (zero power time) reaches τ₂, set power supply at frequency f₁ and power P₁ again;

Step 7: repeat Step 1 to Step 6 until substrate is cleaned.

In step 5, the expanded bubble's volume of Vₙ or diameter w is not necessary to be restricted to be smaller than the dimension Vᵢ or feature size w1 that blocking the features of vias or trenches. It can be certain volume above the Vᵢ, but better to be smaller than the dimension Vᵢ in order to obtain an effective cleaning with shortest process time. And the τ₁ is also not necessary to be restricted to be smaller than τᵢ, but better to be smaller than the τᵢ as being defined in the equation (20).

In step 6, the volume of bubble is not necessary to shrink down to an original volume. It can be certain volume above original volume, but better to be significantly smaller than the Vᵢ to restrict bubble size to get ultra/mega sonic power to be transmitted to the bottom of features such as via, trench, or recessed area.

FIG. 22B shows that the bubble is expanded into a big volume Vₙ by the ultra/mega sonic power working on it during a time τ₁. At this state, the path of mass transfer is partially blocked. And then the fresh chemical cannot thoroughly transfer into the vias or trenches to reach their bottom and sidewall, meanwhile, the particles, residues and other impurities trapped in the vias or trenches cannot go out efficiently. But the state will alternate into the next state for bubble shrinking: when the ultra/mega sonic power is off for cooling the bubble during a time τ₂ as shown in FIG. 22A. In this cooling state, the fresh chemical has chance to transfer into the vias or trenches so as to clean their bottom and sidewall. When the ultra/mega sonic power is on in the next on cycle, the particles, residues and other impurities can be removed out of the vias or trenches by pull out force generated by bubble volume increment. If the two states are alternating in a cleaning process, it achieves a performance of an effective ultra/mega sonic cleaning on a substrate with high aspect ratio features of vias or trenches or recessed areas.

The cooling state in the time τ₂ plays a key role in this cleaning process. It should be defined precisely. And the τ₁<τᵢ, time to restrict bubble size, is desired, and the definition of also is preferred. The following method can determine the time τ₂ to shrink bubble size during a cooling down state and time τ₁ to restrict the bubble expanded to the blockage size experimentally. The experiment is done by using an ultra/mega sonic device coupling with a chemical liquid to clean a pattern substrate with small features of vias and trenches, where the traceable residues exist to evaluate the cleaning performance.

Step 1: choose a τ₁ which is big enough to block the features, which can be calculation as based on the equation (20).

Step 2: choose different time τ₂ to run DOE. The selection of time τ₂ is at least 10 times of τ₁, better to be 100 times of τ₁ at the first screen test.

Step 3: Fix time τ₁ and fix certain power P₀ to run at least five conditions cleaning on specific patterned structure substrate separately. Here, P₀ is the power at which the features of vias or trenches on substrate will be surely not cleaned when running on continuous mode (non-pulse mode).

Step 4: Inspect the traceable residues status inside the features of vias or trenches of above five substrates by SEMS or element analyzer tool such as EDX.

The step 1 to step 4 can be repeated again to gradually shorten the time τ₂ till the traceable residues inside the features of vias or trenches are observed. As the time τ₂ is shorten, the volume of bubble cannot shrink down enough, which will gradually block the features and influence the cleaning performance. This time is called critical cooling time τ_{c}. After knowing critical cooling time τ_{c}, the time τ₂ can be set at value larger than 2τ_{c} to gain safety margin.

A more detail example is shown as follows:

Step 1: choosing 10 different time τ₁ as design of experiment (DOE) conditions, such as τ₁₀, 2τ₁₀, 4τ₁₀, 8τ₁₀, 16τ₁₀, 32τ₁₀, 64τ₁₀, 128τ₁₀, 256τ₁₀, 512τ₁₀, as shown in Table 3;

Step 2: choosing time τ₂ at least 10 times of 512τ₁₀, better to be 20 times of 512τ₁₀ at the first screen test, as shown in Table 3;

Step 3: fixing certain power P₀ to run above ten conditions cleaning on specific patterned structure substrate separately. Here, P₀ is the power at which the features of vias or trenches on substrate will be surely not cleaned when running on continuous mode (non-pulse mode).

TABLE 3

| Substrate# | 1 | 2 | 3 | 4 | 5 | 6 | 7 | 8 | 9 | 10 |
|---|---|---|---|---|---|---|---|---|---|---|
| τ₁ | τ₁₀ | 2τ₁₀ | 4τ₁₀ | 8τ₁₀ | 16τ₁₀ | 32τ₁₀ | 64τ₁₀ | 128τ₁₀ | 256τ₁₀ | 512τ₁₀ |
| τ₂ | 5120τ₁₀ | 5120τ₁₀ | 5120τ₁₀ | 5120τ₁₀ | 5120τ₁₀ | 5120τ₁₀ | 5120τ₁₀ | 5120τ₁₀ | 5120τ₁₀ | 5120τ₁₀ |
| Power | P0 | P0 | P0 | P0 | P0 | P0 | P0 | P0 | P0 | P0 |
| Process Time | T₀ | T₀ | T₀ | T₀ | T₀ | T₀ | T₀ | T₀ | T₀ | T₀ |
| Clean Status | 1 | 2 | 3 | 4 | 5 | 6 | 5 | 4 | 4 | 3 |
| of Features | | | | | | | | | | |

Step 4: Using above conditions as shown in Table 3 to process 10 substrates with features of vias or trenches post plasma etching. The reason to choose the post plasma etched substrate is that the polymers generated during etching process are formed on sidewall of trench and via. Those polymers formed on the bottom or side wall of via are difficulty to remove by a conventional method. Then inspect the cleaning status of features of vias or trenches on the ten substrates by SEMS with crossing section of substrates. The data are shown in Table 3. From the Table 3, the cleaning effect reaches the best point of 6 at τ₁=32τ₁₀, therefore the optimum time τ₁ is 32τ₁₀.

If there is no peak to be found, then the step 1 to step 4 with board time setting of τ₁ can be repeated again to find the time τ₁. After find the initial τ₁, then step 1 to step 4 with time setting close to τ₁ can be repeated again to narrow down the range of time τ₁. After knowing the time τ₁, the time τ₂ can be optimized by reducing the time τ₂ from 512 τ₂ to a value till the cleaning effect is reduced. A detail procedure is disclosed as follows Table 4:

TABLE 4

| Substrate# | 1 | 2 | 3 | 4 | 5 | 6 | 7 | 8 |
|---|---|---|---|---|---|---|---|---|
| τ1 | 32τ₁₀ | 32τ₁₀ | 32τ₁₀ | 32τ₁₀ | 32τ₁₀ | 32τ₁₀ | 32τ₁₀ | 32τ₁₀ |
| τ₂ | 4096τ₁₀ | 2048τ₁₀ | 1024τ₁₀ | 512τ₁₀ | 256τ₁₀ | 128τ₁₀ | 64τ₁₀ | 32τ₁₀ |
| Power | P0 | P0 | P0 | P0 | P0 | P | P0 | P0 |
| Process Time | T₀ | T₀ | T₀ | T₀ | T₀ | T₀ | T₀ | T₀ |
| Clean Status | 3 | 4 | 5 | 6 | 7 | 6 | 5 | 3 |
| of Features | | | | | | | | |

From the Table 4, the cleaning effect reaches the best point of 7 at τ₂=256τ₁₀, therefore the optimum time τ₂ is 256τ₁₀.

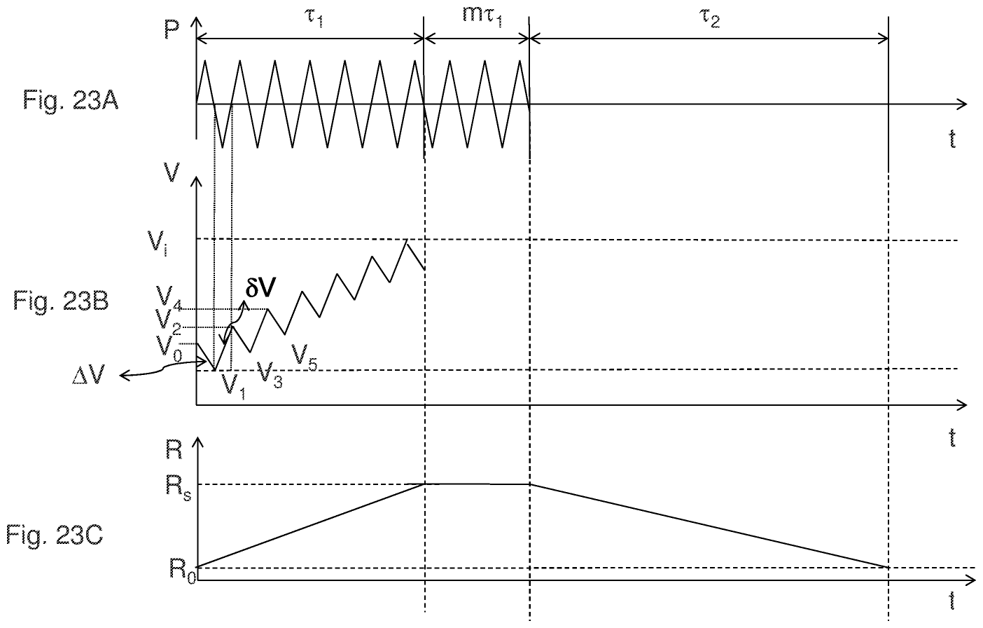

FIGS. 23A to 23C show another embodiment of substrate cleaning method using a ultra/mega sonic device according to the present invention. The method is similar to that shown in FIGS. 22A to 22D, except that power is still on for period of mτ₁ even the cavitation reaches a saturation point Rs. Here, m can be number from 0.1 to 100, preferred 2, which is depending on via and trench structure and chemicals, and it need to be optimized by experiment explained in embodiment as FIGS. 22A to 22D.

Method and apparatus disclosed in FIG. 8 to FIG. 14, and FIG. 16 to FIG. 19 can be applied in embodiments as shown in FIG. 22 and FIG. 23, it will not be described here again.

Generally speaking, an ultra/mega sonic wave with the frequency between 0.1 MHz˜10 MHz may be applied to the method disclosed in the present invention.

As described above, the present invention discloses a method for effectively cleaning vias, trenches or recessed areas on a substrate using ultra/mega sonic device, comprising: applying liquid into a space between a substrate and an ultra/mega sonic device; setting an ultra/mega sonic power supply at frequency f₁ and power P₁ to drive said ultra/mega sonic device; after the ratio of total bubbles volume to volume inside vias, trenches or recessed areas on the substrate increasing to a first set value, setting said ultra/mega sonic power supply at frequency f₂ and power P₂ to drive said ultra/mega sonic device; after the ratio of total bubbles volume to volume inside the vias, trenches or recessed areas reducing to a second set value, setting said ultra/mega sonic power supply at frequency f₁ and power P₁ again; repeating above steps till the substrate being cleaned.

The first set value is below the cavitation saturation point. The second set value is much lower than the cavitation saturate point. The temperature inside bubble cooling down results in the ratio of total bubbles volume to volume inside the vias, trenches or recessed areas reducing to the second set value. The temperature inside bubble cooling down to near temperature of said liquid.

At above embodiment, the first set value is a cavitation saturation point, and even after the ratio of total bubbles volume to volume inside vias, trenches or recessed areas on the substrate reaches to the cavitation saturation point, the ultra/mega sonic power supply is still kept at frequency f₁ and power P₁ for period of mτ₁, here τ₁ is the time to reach the cavitation saturation point, m is multiples of τ₁, which is a number between 0.1 to 100, preferred 2.

According to an embodiment, the present invention discloses an apparatus for effectively cleaning vias, trenches or recessed areas on a substrate using an ultra/mega sonic device. The apparatus includes a chuck, an ultra/mega sonic device, at least one nozzle, an ultra/mega sonic power supply and a controller. The chuck holds a substrate. The ultra/mega sonic device is positioned adjacent to the substrate. The at least one nozzle injects chemical liquid on the substrate and a gap between the substrate and the ultra/mega sonic device. The controller sets the ultra/mega sonic power supply at frequency f₁ and power P₁ to drive the ultra/mega sonic device; after the ratio of total bubbles volume to volume inside vias, trenches or recessed areas on the substrate increasing to a first set value, the controller setting the ultra/mega sonic power supply at frequency f₂ and power P₂ to drive the ultra/mega sonic device; after the ratio of total bubbles volume to volume inside the vias, trenches or recessed areas reducing to a second set value, the controller setting the ultra/mega sonic power supply at frequency f₁ and power P₁ again; repeating above steps till the substrate being cleaned.

According to another embodiment, the present invention discloses an apparatus for effectively cleaning vias, trenches or recessed areas on a substrate using an ultra/mega sonic device. The apparatus includes a cassette, a tank, an ultra/mega sonic device, at least one inlet, an ultra/mega sonic power supply and a controller. The cassette holds at least one substrate. The tank holds the cassette. The ultra/mega sonic device is attached to outside wall of the tank. At least one inlet is used for filling chemical liquid into the tank to immerse the substrate. The controller sets the ultra/mega sonic power supply at frequency f₁ and power P₁ to drive the ultra/mega sonic device; after the ratio of total bubbles volume to volume inside vias, trenches or recessed areas on the substrate increasing to a first set value, the controller setting the ultra/mega sonic power supply at frequency f₂ and power P₂ to drive the ultra/mega sonic device; after the ratio of total bubbles volume to volume inside the vias, trenches or recessed areas reducing to a second set value, the controller setting the ultra/mega sonic power supply at frequency f₁ and power P₁ again; repeating above steps till the substrate being cleaned.

According to another embodiment, the present invention discloses an apparatus for effectively cleaning vias, trenches or recessed areas on a substrate using an ultra/mega sonic device. The apparatus includes a chuck, an ultra/mega sonic device, a nozzle, an ultra/mega sonic power supply and a controller. The chuck holds a substrate. The ultra/mega sonic device coupled with a nozzle is positioned adjacent to the substrate. The nozzle injects chemical liquid on the substrate. The controller sets the ultra/mega sonic power supply at frequency f₁ and power P₁ to drive the ultra/mega sonic device; after the ratio of total bubbles volume to volume inside vias, trenches or recessed areas on the substrate increasing to a first set value, the controller setting the ultra/mega sonic power supply at frequency f₂ and power P₂ to drive the ultra/mega sonic device; after the ratio of total bubbles volume to volume inside the vias, trenches or recessed areas reducing to a second set value, the controller setting the ultra/mega sonic power supply at frequency f₁ and power P₁ again; repeating above steps till the substrate being cleaned.

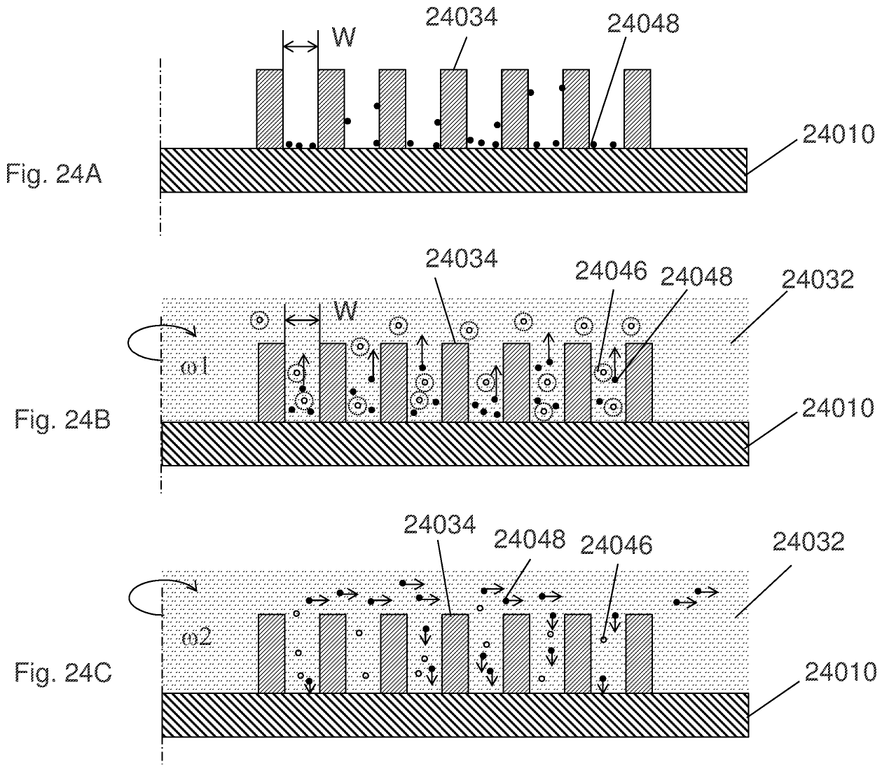

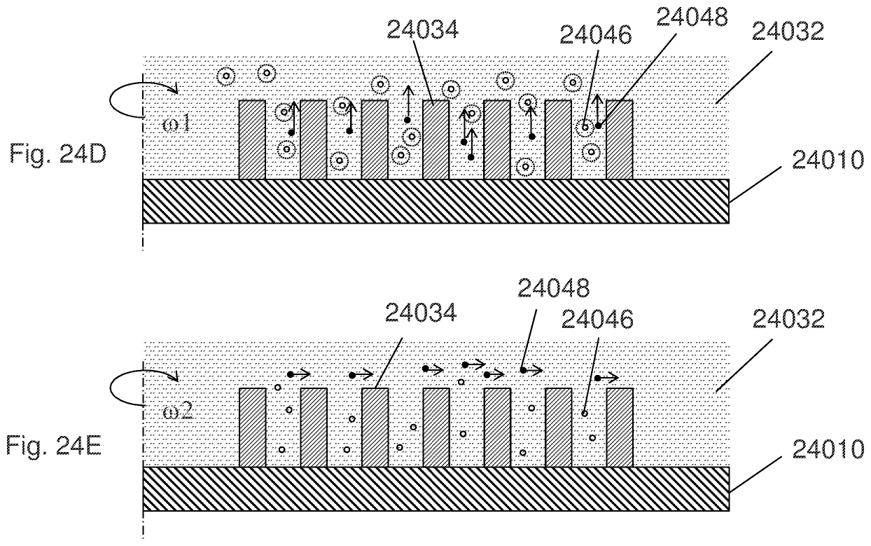

Referring to FIGS. 24A-24E, an operation process to remove impurities 24048, e.g., particles, residues and/or other impurities trapped in features 24034 of patterned structures on a semiconductor wafer 24010 using acoustic energy according to the present invention is disclosed below. The following steps may be performed in orders other than step 1 to step 5.

Step 1: Place a semiconductor wafer 24010 comprising features 24034 of patterned structures on a base, e.g., a spin chuck. The base is capable of rotating the semiconductor wafer 24010 at a given speed. A line width W of the features may be no more than 60 nanometers.

Step 2: Apply cleaning liquid 24032, e.g., chemical liquid or gas (hydrogen, nitrogen, oxygen, NH₃, or CO₂) doped water on the semiconductor wafer 24010 using an outlet. The outlet may be a nozzle that injects or sprays the cleaning liquid 24032 on the semiconductor wafer 24010. The semiconductor wafer 24010 may be rotated as the cleaning liquid 24032 is being applied.

Step 3: As shown in FIG. 24B, rotate the semiconductor wafer 24010 at a low speed ω1, e.g., 10 RPM (revolutions per minute) to 100 RPM or 200 RPM when acoustic energy is being applied to the cleaning liquid 24032. For example, to apply acoustic energy, an ultra or mega sonic device may be placed adjacent to the surface of the semiconductor wafer 24010, wherein the cleaning liquid 24032 is filled between the ultra or mega sonic device and the semiconductor wafer 24010 due to the low rotation speed and the position of the ultra or mega sonic device. More specifically, due to surface tension of the cleaning liquid 24032, the cleaning liquid 24032 is filled up within the gap between the semiconductor wafer 24010 and the ultra or mega sonic device under a certain combination of settings including rotation speed of the spin chuck, distance of the gap between the semiconductor wafer 24010 and the ultra or mega sonic device, flow rate of the cleaning liquid 24032 and physical property of the cleaning liquid 24032. When a power supply of the ultra or mega sonic device is turned on, bubbles 24046 are generated, and a cleaning process on the semiconductor wafer 24010 using acoustic energy is started. As shown in FIG. 24B, the impurities 24048 trapped in the features 24034 are lifted up due to the acoustic energy generated by the ultra or mega sonic device. The time duration of step 3 may be, for example, one second to a few minutes.

Step 4: As shown in FIG. 24C, rotate the semiconductor wafer 24010 at a high speed ω2, e.g., 100 RPM or 200 RPM to 1500 RPM when acoustic energy is not being applied to the cleaning liquid 24032. For example, to stop applying acoustic energy, the power supply of the ultra or mega sonic device may be turned off, and/or the ultra or mega sonic device may be raised up from the position adjacent to the semiconductor wafer 24010 to a position above the liquid level. When the rotation speed of the semiconductor wafer 24010 is increased, a tangential velocity of the cleaning liquid 24032 on the surface of the semiconductor wafer 24010 is increased because the cleaning liquid 24032 on the surface of the semiconductor wafer 24010 is rotated along with the spin chuck. As shown in FIG. 24C, increasing the tangential velocity of the cleaning liquid 24032 enhances the removal efficiency of the impurities 24048 which are lifted up by step 3. Impurities 24048 move laterally towards the edge of the semiconductor wafer 24010, and eventually move away from the semiconductor wafer 24010. The time duration of step 4 may be, for example, one second to a few minutes. In this step, the application of acoustic energy is stopped, and the bubbles 24046 remain in a static state. In this step, before increasing the rotation speed of the base for rotating the semiconductor wafer 24010 at a high speed w2, the ultra or mega sonic device is preferably raised from the position adjacent to the surface of the semiconductor wafer, which is more conducive to removal of the impurities 24048.

Step 5: Optionally, as shown in FIGS. 24D-24E, repeat step 3 and step 4 for one or more cycles, so as to remove the impurities 24048 that have fallen back into or are remaining inside the features 24034. As shown in FIGS. 24B-24C, a portion of the impurities 24048 would be lifted up by step 3 far away from the patterned structures of the semiconductor wafer 24010. This portion of impurities 24048 are easily removed in step 4 by the outward liquid flow due to the increased rotation speed of the semiconductor wafer 24010. However, another portion of the impurities 24048 are still inside the patterned structures or near the patterned structures, and would fall back into the features 24034 because application of acoustic energy has stopped, and are still trapped inside the features 24034 after step 4. Therefore, repeating step 3 and step 4 for one or more cycles can remove the impurities 24048 more effectively, as shown in FIGS. 24D-24E.

In step 3, the cleaning process using acoustic energy may be applied according to steps 4 to 6 described in connection to FIGS. 7A to 7C, or any of FIGS. 8A-14B. In this way, the bubbles may be cooled down to avoid damaging implosion or blocking of the patterned structures.

In the process of cleaning the patterned structures by the chemical liquid or gas doped water with acoustic energy being applied, the bubbles will be expanded by the acoustic energy. There is a risk that the features of vias, trenches and/or recessed areas will be blocked by the bubbles, especially when the aspect ratio (depth/width) is 3 or more. Therefore, fresh liquid cannot effectively reach the bottom of the vias, trenches and/or recessed areas, and the particles, residues or other impurities at the bottom of such deep vias, trenches and/or recessed areas cannot be effectively removed or cleaned. In the features of patterned structures, saturation point R_{S} is defined by the largest amount of bubbles inside the features of vias, trenches or recessed areas. Over the saturation point, cleaning liquid is blocked by the bubbles inside the features and hardly reaches the bottom or side walls of the features of vias, trenches or recessed areas, so that the cleaning performance of the cleaning liquid is impaired. Below the saturation point, the cleaning liquid has enough access inside the features of vias, trenches or recessed areas, and a good cleaning performance is achieved.

Since the total volume of bubbles in the features of vias, trenches or recessed areas are related to both the number of bubbles and the size of bubbles in the features of vias, trenches or recessed areas, the control of the number of bubbles and the size of bubbles is critical for the cleaning performance in the high aspect ratio features cleaning process. A method, as shown in FIGS. 21A to 21D, to control the volume of single bubble has been disclosed and will not be discussed in detail here.

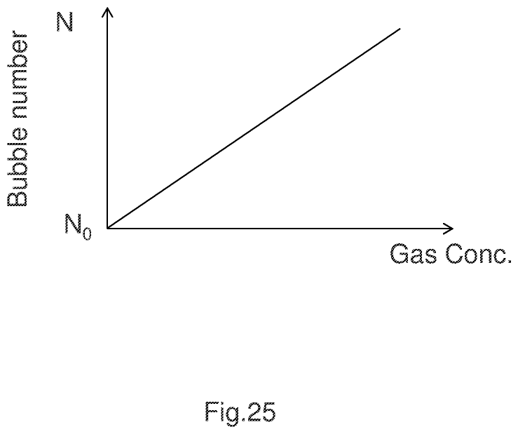

FIG. 25 shows a relationship between the number of bubbles and the gas concentration in the cleaning liquid. In order to control the gas concentration in the cleaning liquid, the gas amount doped in the cleaning liquid needs to be controlled precisely by this apparatus. Validation experiments should be done using different gas doping amount with acoustic energy being applied to clean a patterned substrate comprising small features of vias, trenches or recessed areas, after the ultra or mega sonic cleaning process parameters are optimized, to determine the appropriate gas concentration. The optimal gas concentration is determined by the optimal cleaning effect which can be obtained by experiments.

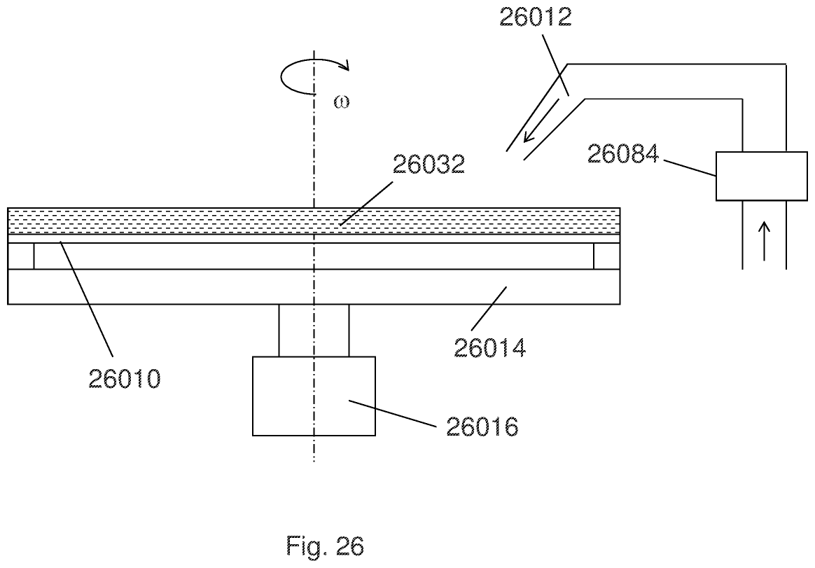

FIG. 26 shows another exemplary semiconductor wafer cleaning apparatus. The apparatus is similar to that shown in FIG. 1A, except that this apparatus has a de-bubble device 26084. The de-bubble device 26084 may be set on a passage that leads to the nozzle 26012. The cleaning liquid 26032 flows through the de-bubble device 26084 and is supplied to the nozzle 26012. The nozzle 26012 delivers the cleaning liquid 26032 onto the semiconductor wafer 26010 which is placed on the spin chuck 26014 being rotated by the rotation driving mechanism 26016. The de-bubble device 26084 blocks large bubbles but does not block small bubbles, that is to say, the small bubbles are capable of flowing through the de-bubble device 26084 along with the cleaning liquid but the large bubbles cannot. The de-bubble device 26084 removes the large bubbles in the cleaning liquid before the cleaning liquid is supplied to the nozzle 26012, which helps with reducing damaging implosion or blocking of the patterned structures on the semiconductor wafer 26010 during the process of cleaning the patterned structures by the cleaning liquid with acoustic energy being applied.

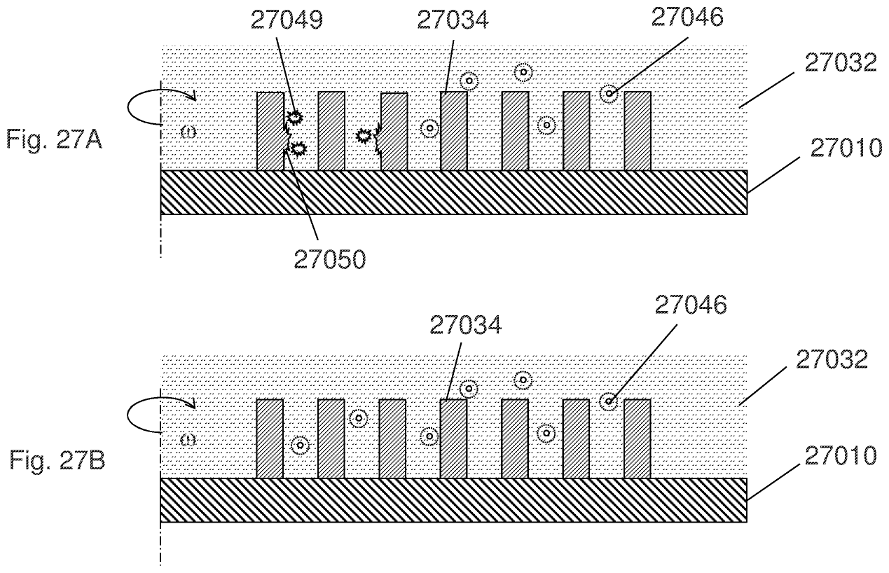

FIG. 27A shows a semiconductor wafer 27010 having one or more defects 27050, e.g., scums or burrs in the features 27034, which have impact on the feature surface smoothness, such as residual surface contaminants and surface textures due to crystal anisotropy etching. In the process of cleaning the features of vias, trenches or recessed areas by a cleaning liquid 27032 such as chemical liquid or gas doped water with acoustic energy being applied, bubbles 27046 may accumulate around the locations of defects 27050, such that collapse of the bubbles 27046 is easier to occur there due to strain concentration caused by the defects 27050. Mechanical force of micro jet generated by the bubble collapse will further lead to the damage of the fine features 27034.

To solve this problem, a method of pretreatment is needed to remove the defects 27050 and obtain a smooth surface of the patterned structures, as shown in FIG. 27B.

In an embodiment, a descum process is performed in advance to the cleaning process, using high energy plasma to remove the scums on the patterned structures 27034 and form a smooth surface of the patterned structures 27034. Then the steps disclosed in connection to FIGS. 24A to 24E may be performed according to the present invention.

In another embodiment, the high energy plasma is used to remove or smooth the burrs on the patterned structures 27034 in advance to the cleaning process, to obtain a smooth surface of the patterned structures. Then the steps disclosed in connection to FIGS. 24A to 24E may be performed according to present invention.

In an embodiment, a wet pretreatment process is performed to remove or smooth the burrs on the patterned structures 27034, including the following steps. The following steps may be performed in orders other than step 1 to step 5.

Step 1: Place a semiconductor wafer comprising features of pattern structures on a base, e.g., a spin chuck.

Step 2: Apply a pretreatment liquid, or provide more than one pretreatment liquids one after another, on the semiconductor wafer using an outlet, to remove or smooth the burrs on the patterned structures. The outlet may be a nozzle that injects or sprays the pretreatment liquid on the semiconductor wafer. The semiconductor wafer may be rotated as the one or more pretreatment liquids are being applied.

Step 3: Apply deionized (DI) water to rinse the pretreatment liquid on the semiconductor wafer.

Subsequently, step 2 to step 5 in the method disclosed in connection to FIGS. 24A to 24E may be performed to clean the semiconductor wafer with patterned structures.

The pretreatment liquid for silicon surface pretreatment can be SC1 liquid (mixture of H₂O, H₂O₂ and NH₄OH). Multiple pretreatment liquids can also be applied as follows: applying ozone liquid (a certain amount of ozone dissolved in water) on the surface of the semiconductor wafer at first to form a condensed oxidation film for silicon passivation; applying DI water for rinsing the remaining chemical on the semiconductor wafer; and applying diluted hydrogen fluoride (DHF) on the surface of the semiconductor wafer to etch the oxide on the surface of the semiconductor wafer, to achieve an under-cut effect of the particles, residues or other impurities. This way, the particles, residues or other impurities are much easier to remove in the subsequent cleaning steps.

In some aspects of the present disclosure, rotation of the base and application of acoustic energy may be controlled by one or more controllers, for example software programmable control of the equipment. The one or more controllers may comprise one or more timers to control the timing of rotation and/or energy application.

The present invention may be applied to a device manufacturing node of the semiconductor wafer which is no more than 45 nanometers, and a line width which is no more than 60 nanometers.

The present invention may be applied to 3D NAND.

Methods disclosed in FIG. 7A to FIG. 14B and FIG. 18A to FIG. 23C, and apparatuses disclosed in FIG. 1A, FIG. 16 and FIG. 17 can be applied in embodiments as shown in FIG. 24A to FIG. 27B.

Although the present invention has been described with respect to certain embodiments, examples, and applications, it will be apparent to those skilled in the art that various modifications and changes may be made without departing from the invention.

What is claimed is:

1. A method for cleaning a substrate comprising features of patterned structures, the method comprising:
placing the substrate on a substrate holder configured to rotate the substrate;
applying cleaning liquid on the substrate;
rotating the substrate by the substrate holder at a first rate when acoustic energy is being applied to the cleaning liquid by a transducer; and
rotating the substrate by the substrate holder at a second rate higher than the first rate when acoustic energy is not being applied to the cleaning liquid by the transducer.

2. The method of claim 1, wherein the steps of rotating the substrate at a first rate when acoustic energy is being applied and rotating the substrate at a second rate when acoustic energy is not being applied are alternately applied one after another for a number of cycles.

3. The method of claim 1, wherein the first rate is from 10 revolutions per minute to 200 revolutions per minute.

4. The method of claim 1, wherein the second rate is from 100 revolutions per minute to 1500 revolutions per minute.

5. The method of claim 1, wherein rotating the substrate at a first rate when acoustic energy is being applied comprises:
controlling, based on a timer, a power supply of the transducer to deliver acoustic energy to the cleaning liquid at a first frequency and a first power level for a predetermined first time period; and
controlling, based on the timer, the power supply of the transducer to deliver acoustic energy to the cleaning liquid at a second frequency and a second power level for a predetermined second time period.

6. The method of claim 5, wherein the first and second time periods, the first and second power levels, and the first and second frequencies are determined such that a percentage of damaged features as a result of delivering the acoustic energy is lower than a predetermined threshold.

7. The method of claim 1, wherein a device manufacturing node of the substrate is 45 nanometers or smaller than 45 nanometers.

8. The method of claim 1, wherein a line width of the features of patterned structures is 60 nanometers or smaller than 60 nanometers.

9. The method of claim 1, wherein a depth to width aspect ratio of the features of patterned structures is 3 or larger than 3.

10. The method of claim 1, further comprising moving the transducer away from the cleaning liquid after rotating the substrate at a first rate when acoustic energy is being applied and before rotating the substrate at a second rate when acoustic energy is not being applied.

11. The method of claim 1, further comprising performing pretreatment on the substrate to remove defects that attract bubbles before applying cleaning liquid on the substrate.

12. The method of claim 1, further comprising performing pretreatment on the cleaning liquid to remove at least a part of bubbles within the cleaning liquid before applying cleaning liquid on the substrate.

13. A method for cleaning a substrate comprising features of patterned structures, the method comprising:
performing pretreatment on the substrate to remove defects that attract bubbles;
applying a cleaning liquid on the substrate;
controlling, based on a timer, a power supply of a transducer to deliver acoustic energy to the cleaning liquid at a first frequency and a first power level for a predetermined first time period; and
controlling, based on the timer, the power supply of the transducer to deliver acoustic energy to the cleaning liquid at a second frequency and a second power level for a predetermined second time period,
wherein the first and second time periods are alternately applied one after another for a predetermined number of cycles.

14. The method of claim 13, wherein the first and second time periods, the first and second power levels, and the first and second frequencies are determined such that a percentage of damaged features as a result of delivering the acoustic energy is lower than a predetermined threshold.

15. The method of claim 13, wherein the pretreatment comprises applying plasma energy on the substrate.

16. The method of claim 13, wherein the pretreatment comprises applying one or more pretreatment liquids on the substrate.

17. The method of claim 16, wherein applying one or more pretreatment liquids on the substrate comprises applying SC1 liquid.

18. The method of claim 16, wherein applying one or more pretreatment liquids on the substrate comprises:
applying ozone liquid on the substrate;
applying deionized water on the substrate; and
applying diluted hydrogen fluoride on the substrate.

19. A method for cleaning a substrate comprising features of patterned structures, the method comprising:
performing pretreatment on a cleaning liquid to remove at least a part of bubbles within the cleaning liquid;
applying the cleaning liquid on the substrate;
controlling, based on a timer, a power supply of a transducer to deliver acoustic energy to the cleaning liquid at a first frequency and a first power level for a predetermined first time period; and
controlling, based on the timer, the power supply of the transducer to deliver acoustic energy to the cleaning liquid at a second frequency and a second power level for a predetermined second time period,
wherein the first and second time periods are alternately applied one after another for a predetermined number of cycles.

20. The method of claim 19, wherein the pretreatment comprises substantially removing bubbles larger than a threshold size.

21. An apparatus for cleaning a substrate comprising features of patterned structures, the apparatus comprising:
a substrate holder configured to hold the substrate and configured to rotate the substrate;
an inlet configured to apply cleaning liquid on the substrate;
a transducer configured to deliver acoustic energy to the liquid; and
one or more controllers configured to:
control the substrate holder to rotate the substrate at a first rate while controlling the transducer to deliver acoustic energy to the cleaning liquid, and
control the substrate holder to rotate the substrate at a second rate higher than the first rate while controlling the transducer not to deliver acoustic energy to the cleaning liquid.

22. The apparatus of claim 21, wherein the substrate holder comprises a rotating chuck.

23. The apparatus of claim 21, wherein the inlet comprises a nozzle configured to spray the cleaning liquid on the substrate.

24. The apparatus of claim 21, wherein the one or more controllers are further configured to alternately rotate the substrate at a first rate when acoustic energy is being applied and rotate the substrate at a second rate when acoustic energy is not being applied for a number of cycles.

25. The apparatus of claim 21, wherein the first rate is from 10 revolutions per minute to 200 revolutions per minute.

26. The apparatus of claim 21, wherein the second rate is from 100 revolutions per minute to 1500 revolutions per minute.

27. The apparatus of claim 21, wherein:
the transducer comprises a power supply;
the one or more controllers comprise a timer; and
the one or more controllers are further configured to, when rotating the substrate at a first rate:
control, based on the timer, the power supply of the transducer to deliver acoustic energy to the cleaning liquid at a first frequency and a first power level for a predetermined first time period, and
control, based on the timer, the power supply of the transducer to deliver acoustic energy to the cleaning liquid at a second frequency and a second power level for a predetermined second time period after the first time period.

28. The apparatus of claim 21, wherein a device manufacturing node of the substrate is 45 nanometers or smaller than 45 nanometers.

29. The apparatus of claim 21, wherein a line width of the features of patterned structures is 60 nanometers or smaller than 60 nanometers.

30. The apparatus of claim 21, wherein a depth to width aspect ratio of the features of patterned structures is 3 or larger than 3.

31. The apparatus of claim 21, wherein the one or more controllers are further configured to move the transducer away from the cleaning liquid after rotating the substrate at a first rate when acoustic energy is being applied and before rotating the substrate at a second rate when acoustic energy is not being applied.

32. The apparatus of claim 21, further comprising a plasma source configured to apply plasma energy on the substrate before applying the cleaning liquid on the substrate.

33. The apparatus of claim 21, wherein the inlet is further configured to apply one or more pretreatment liquids on the substrate before applying the cleaning liquid on the substrate.

34. The apparatus of claim 33, wherein the one or more pretreatment liquids comprise SC1 liquid.

35. The apparatus of claim 33, wherein the one or more pretreatment liquids comprise ozone liquid, deionized water, and diluted hydrogen fluoride.

36. The apparatus of claim 21, further comprising a debubbler coupled to the inlet configured to remove at least a part of bubbles within the cleaning liquid.

37. The apparatus of claim 36, wherein the debubbler is further configured to substantially remove bubbles larger than a threshold size.

38. A controller for an apparatus for cleaning a substrate, the controller being configured to:
control a substrate holder to rotate the substrate at a first rate while controlling a transducer to deliver acoustic energy to cleaning liquid applied on the substrate; and
control the substrate holder to rotate the substrate at a second rate higher than the first rate while controlling the transducer not to deliver acoustic energy to the cleaning liquid.

39. The controller of claim 38, further comprising a timer, wherein the controller is further configured to:
control, based on the timer, a power supply of the transducer to deliver acoustic energy to the cleaning liquid at a first frequency and a first power level for a predetermined first time period; and
control, based on the timer, the power supply of the transducer to deliver acoustic energy to the cleaning liquid at a second frequency and a second power level for a predetermined second time period after the first time period.

40. The controller of claim 39, wherein the second power level is zero.
